(19) United States
(12) Patent Application Publication
(10) Pub. No.: US 2021/0265602 A1
(43) Pub. Date: Aug. 26, 2021

(54) VAPOR DEPOSITION MASK, METHOD FOR MANUFACTURING VAPOR DEPOSITION MASK, AND METHOD FOR MANUFACTURING ORGANIC SEMICONDUCTOR ELEMENT

(71) Applicant: SAKAI DISPLAY PRODUCTS CORPORATION, Sakai-shi, Osaka (JP)

(72) Inventors: SUSUMU SAKIO, Sakai-shi, Osaka (JP); KATSUHIKO KISHIMOTO, Sakai-shi, Osaka (JP)

(21) Appl. No.: 17/265,707

(22) PCT Filed: Aug. 8, 2018
(86) PCT No.: PCT/JP2018/029811

§ 371 Date: Feb. 3, 2021

(51) Int. Cl. H01L 51/56; H01L 51/00; C23C 14/34; C23C 14/08; C23C 14/04; C23C 16/04

(52) U.S. Cl. CPC H01L 51/56; H01L 51/0011; C23C 14/34; H01L 27/3206; C23C 14/042; C23C 16/042; C23C 14/083

(57) ABSTRACT

A vapor deposition mask (100) including: a magnetic metal member (20) including at least one first opening (25); and a layered member (30) that is arranged on the magnetic metal member (20) so as to cover the at least one first opening (25) and has a plurality of second openings (13) located in the at least one first opening (25), wherein: the layered member (30) includes a first layer (m1) and a second layer (m2) that is arranged between the first layer (m1) and the magnetic metal member (20); and in the at least one first opening (25), at a first temperature that is greater than or equal to room temperature, an elastic modulus E1 of the first layer, a thickness a1 of the first layer, an internal stress σ1 of the first layer, an elastic modulus E2 of the second layer, a thickness a2 of the second layer and an internal stress σ2 of the second layer (where σ1 and σ2 are positive for tensile stress) satisfy Expressions (1) and (2) below:

σ1/E1−σ2/E2<0 (1)

0<a1×σ1+a2×σ2 (2).

### TECHNICAL FIELD

The present invention relates to a vapor deposition mask and a method for manufacturing a vapor deposition mask. The present invention also relates to a method for manufacturing an organic semiconductor device using a vapor deposition mask.

### BACKGROUND ART

In recent years, organic EL (Electro Luminescent) display devices have been drawing public attention as a display of the next generation. With organic EL display devices that are currently mass-produced, the formation of an organic EL layer is primarily done by using a vacuum deposition method.

Typically, a mask made of a metal (a metal mask) is used as the vapor deposition mask. However, with the increasing definition of organic EL display devices, it is becoming difficult to precisely form a vapor deposition pattern using a metal mask. This is because it is difficult with current metal processing techniques to precisely form small openings corresponding to a short pixel pitch (e.g., about 10 to 20 μm) in a metal plate (e.g., a thickness of about 100 μm) to be the metal mask.

In view of this, a vapor deposition mask (hereinafter referred to also as a “layered mask”) having a structure in which a resin layer and a metal layer (a magnetic metal member) are layered together has been proposed in the art as a vapor deposition mask for forming a vapor deposition pattern with a high definition.

For example, Patent Document No. 1 discloses a layered mask including a resin film layered with a hold member, which is a metal magnetic member. A plurality of openings corresponding to an intended vapor deposition pattern are formed in the resin film. Slits whose size is larger than the openings of the resin film are formed in the hold member. The openings of the resin film are arranged in the slits. Therefore, when the layered mask of Patent Document No. 1 is used, the vapor deposition pattern is formed corresponding to the plurality of openings of the resin film. Even small openings can be formed with a high precision in a resin film that is thinner than an ordinary metal plate used for a metal mask.

When forming small openings as described above in the resin film, a laser ablation method is suitably used. Patent Document No. 1 describes a method in which a resin film placed on a support member (e.g., a glass substrate) is irradiated with a laser so as to form openings of an intended size.

FIGS. 21(a) to 21(d) are schematic process cross-sectional views illustrating a conventional method for manufacturing a vapor deposition mask disclosed in Patent Document No. 1.

According to Patent Document No. 1, first, as shown in FIG. 21(a), a metal layer 82 having openings (slits) 85 therein is formed on a resin film 81, thereby obtaining a layered film 80. Next, as shown in FIG. 21(b), the layered film 80 is attached to a frame 87 with tension in a predetermined in-plane direction(s) applied on the layered film 80. Thereafter, the layered film 80 is placed on a glass substrate 90 as shown in FIG. 21(c). In this process, a surface of the resin film 81 that is opposite from the metal layer 82 is made to adhere to the glass substrate 90 with a liquid 88 such as ethanol therebetween. Thereafter, as shown in FIG. 21(d), portions of the resin film 81 that are exposed through the slits 85 of the metal layer 82 are irradiated with a laser beam L, thereby forming a plurality of openings 89 in the resin film 81. Thus, a layered vapor deposition mask 900 is manufactured.

Note that the magnetic metal member (the metal layer 82), which is the hold member, is a vapor deposition mask for forming a plurality of devices (e.g., organic EL displays) on a single substrate to be vapor-deposited, wherein two or more openings or slits are arranged for a unit region U that corresponds to one device, in the example described above. However, there may be one opening for one unit region U. Such a structure is referred to as an “open mask structure”. Hereinafter, a magnetic metal member having an open mask structure may be referred to simply as an “open mask”.

### CITATION LIST

### Patent Literature

Patent Document No. 1: Japanese Laid-Open Patent Publication No. 2014-205870

### SUMMARY OF INVENTION

### Technical Problem

As a result of a study, the present inventors found that with conventional vapor deposition masks produced by the method illustrated in FIG. 21, the resin film may deflect due to its own weight.

If the resin film deflects, or the like, it may be difficult to make the finished vapor deposition mask adhere to the substrate to be vapor-deposited (hereinafter referred to as the “vapor deposition substrate”), and a gap may be produced between the vapor deposition mask and the vapor deposition substrate. Therefore, when a vapor deposition pattern is formed by using a conventional vapor deposition mask, the vapor deposition pattern is formed to be more spread than the intended shape, thereby blurring the boundary of the vapor deposition pattern (hereinafter referred to as “vapor deposition blur”), possibly failing to realize a vapor deposition pattern having a high definition. As a result, color mixing may occur between adjacent pixels of red pixels (R), green pixels (G) and blue pixels (B), thus lowering the display quality.

The present invention has been made in view of the above, and an object thereof is to provide a layered vapor deposition mask that can suitably be used for forming a vapor deposition pattern having a high definition, and a method for manufacturing the same. Another object of the present invention is to provide a method for manufacturing an organic semiconductor device using such a vapor deposition mask.

### Solution to Problem

A vapor deposition mask according to one embodiment of the present invention includes: a magnetic metal member including at least one first opening; and a layered member that is arranged on the magnetic metal member so as to cover the at least one first opening and has a plurality of second openings located in the at least one first opening, wherein: the layered member includes a first layer and a second layer that is arranged between the first layer and the magnetic metal member; and in the at least one first opening, at a first temperature that is greater than or equal to room temperature, an elastic modulus E1 of the first layer, a thickness a1 of the first layer, an internal stress σ1 of the first layer, an elastic modulus E2 of the second layer, a thickness a2 of the second layer and an internal stress σ2 of the second layer (where σ1 and σ2 are positive for tensile stress) satisfy Expressions (1) and (2) below:

σ1/E1−σ2/E2<0 (1)

0<a1×σ1+a2×σ2 (2).

In one embodiment, the first temperature is greater than or equal to room temperature and less than or equal to 60° C.

In one embodiment, at the first temperature, a portion of the layered member that is located in the at least one first opening is warped so as to protrude toward a side opposite to the magnetic metal member.

In one embodiment, the vapor deposition mask further includes an adhesive layer that is located between the layered member and the magnetic metal member and attaches together the layered member and the magnetic metal member.

In one embodiment, the first layer and the second layer are each a resin layer or formed from an inorganic material other than a metal material.

In one embodiment, either one of the first layer and the second layer is a metal layer.

In one embodiment, at least one of the first layer and the second layer is a resin layer.

In one embodiment, the first layer and the second layer are both resin layers.

In one embodiment, at least one of the first layer and the second layer is a polyimide layer.

In one embodiment, the first layer is formed by using a polyimide layer and the second layer is formed by using an actinically-curable resin material.

In one embodiment, the first layer is formed by using a polyimide layer and the second layer is formed by using an inorganic material other than a metal material.

In one embodiment, only the layered member is arranged so as to cover the at least one first opening of the magnetic metal member, and the layered member is made only of the first layer and the second layer.

In one embodiment, the vapor deposition mask further includes a frame that supports the magnetic metal member.

In one embodiment, the magnetic metal member has an open mask structure.

A method for manufacturing a vapor deposition mask according to one embodiment of the present invention includes the steps of: (A) providing a magnetic metal member having at least one first opening; (B) providing a substrate; (C) forming a layered member on a surface of the substrate, the layered member including a first layer and a second layer formed on the first layer; (D) securing the layered member formed on the surface of the substrate on the magnetic metal member so as to cover the at least one first opening; (E) forming a plurality of second openings in the layered member; and (F) removing the layered member from the substrate, wherein in the at least one first opening, at a first temperature that is greater than or equal to room temperature, an elastic modulus E1 of the first layer, a thickness a1 of the first layer, an internal stress σ1 of the first layer, an elastic modulus E2 of the second layer, a thickness a2 of the second layer and an internal stress σ2 of the second layer (where σ1 and σ2 are positive for tensile stress) satisfy Expressions (1) and (2) below:

σ1/E1−σ2/E2<0 (1)

0<a1×σ1+a2×σ2 (2).

In one embodiment, at least one of the first layer and the second layer is a resin layer; and the step (C) includes a step of forming the resin layer by applying a solution including a resin material or a varnish of a resin material and then performing a heat treatment.

In one embodiment, the resin layer is a polyimide layer.

In one embodiment, the step (F) is performed after the step (E).

In one embodiment, the method further includes the step of providing a frame along a peripheral edge portion of the magnetic metal member.

In one embodiment, the first layer and the second layer are each formed by using a resin material or by using an inorganic material other than a metal material.

In one embodiment, the first layer and the second layer are both resin layers.

In one embodiment, either one of the first layer and the second layer is a metal layer.

In one embodiment, the substrate is a glass substrate, and a thermal expansion coefficient of the glass substrate is generally equal to or less than a thermal expansion coefficient of a material of each of the first layer and the second layer.

In one embodiment, the first temperature is less than or equal to 60° C.

In one embodiment, the magnetic metal member has an open mask structure.

A method for manufacturing an organic semiconductor device according to one embodiment of the present invention includes a step of vapor-depositing an organic semiconductor material on a work at the first temperature using one of the vapor deposition masks set forth above.

### Advantageous Effects of Invention

An embodiment of the present invention provides a layered vapor deposition mask that can suitably be used for the formation of a vapor deposition pattern having a high definition, and a method for manufacturing the same.

### BRIEF DESCRIPTION OF DRAWINGS

FIG. 1(a) is a plan view schematically showing a vapor deposition mask 100 according to an embodiment of the present invention, and FIG. 1(b) is a cross-sectional view taken along line 1B-1B′ of FIG. 1(a).

FIG. 2 is a schematic enlarged cross-sectional view of a portion of a layered member 10 of the vapor deposition mask 100.

FIG. 3(a) is a schematic cross-sectional view of the vapor deposition mask 100, and FIG. 3(b) is a cross-sectional view illustrating a vapor deposition step using the vapor deposition mask 100.

FIGS. 4(a) and 4(b) are a process plan view illustrating a method for manufacturing a vapor deposition mask according to an embodiment of the present invention, and a process cross-sectional view taken along line 4B-4B′, respectively.

FIGS. 5(a) and 5(b) are a process plan view illustrating a method for manufacturing a vapor deposition mask according to an embodiment of the present invention, and a process cross-sectional view taken along line 5B-5B′, respectively.

FIGS. 6(a) and 6(b) are a process plan view illustrating a method for manufacturing a vapor deposition mask according to an embodiment of the present invention, and a process cross-sectional view taken along line 6B-6B′, respectively.

FIGS. 7(a) and 7(b) are a process plan view illustrating a method for manufacturing a vapor deposition mask according to an embodiment of the present invention, and a process cross-sectional view taken along line 7B-7B′, respectively.

FIGS. 8(a) and 8(b) are a process plan view illustrating a method for manufacturing a vapor deposition mask according to an embodiment of the present invention, and a process cross-sectional view taken along line 8B-8B′, respectively.

FIGS. 9(a) to 9(e) are process cross-sectional views each illustrating another method for manufacturing a vapor deposition mask according to an embodiment of the present invention.

FIGS. 10(a) to 10(e) are process cross-sectional views each illustrating still another method for manufacturing a vapor deposition mask according to an embodiment of the present invention.

FIGS. 11(a) to 11(e) are process cross-sectional views each illustrating still another method for manufacturing a vapor deposition mask according to an embodiment of the present invention.

FIGS. 12(a) to 12(e) are process cross-sectional views each illustrating still another method for manufacturing a vapor deposition mask according to an embodiment of the present invention.

FIG. 13(a) is a top view of Samples A to C, and FIG. 13(b) is a schematic cross-sectional view illustrating the deformation of substrates of the samples.

FIGS. 14(a) and 14(b) are views schematically showing the layered member 10 at the temperature T0 and the temperature T1, respectively.

FIG. 15 is a schematic cross-sectional view showing a variation of a vapor deposition mask according to an embodiment of the present invention.

FIGS. 16(a) and 16(b) are plan views each schematically showing another vapor deposition mask according to an embodiment of the present invention.

FIG. 17 is a cross-sectional view schematically showing an organic EL display device 500 of a top emission type.

FIGS. 18(a) to 18(d) are process cross-sectional views showing a manufacturing process of the organic EL display device 500.

FIGS. 19(a) to 19(d) are process cross-sectional views showing a manufacturing process of the organic EL display device 500.

FIGS. 20(a) to 20(d) are schematic cross-sectional views illustrating how a burr is produced on a resin film by a laser ablation method.

FIGS. 21(a) to 21(d) are schematic process cross-sectional views each illustrating a method for manufacturing a conventional vapor deposition mask disclosed in Patent Document No. 1.

FIG. 22(a) is a schematic cross-sectional view of a vapor deposition mask 800 of a reference example, and FIG. 22(b) is a cross-sectional view illustrating a vapor deposition step using the vapor deposition mask 800.

### DESCRIPTION OF EMBODIMENTS

With a conventional vapor deposition mask of a layered type, factors for the blur of the boundary of the vapor deposition pattern (the vapor deposition blur) include the deflection of the resin film, and a burr, or the like, occurring when processing the resin film. Regarding the burr and the deflection of the resin film, a study by the present inventors resulted in the following findings.

<Regarding Burr>

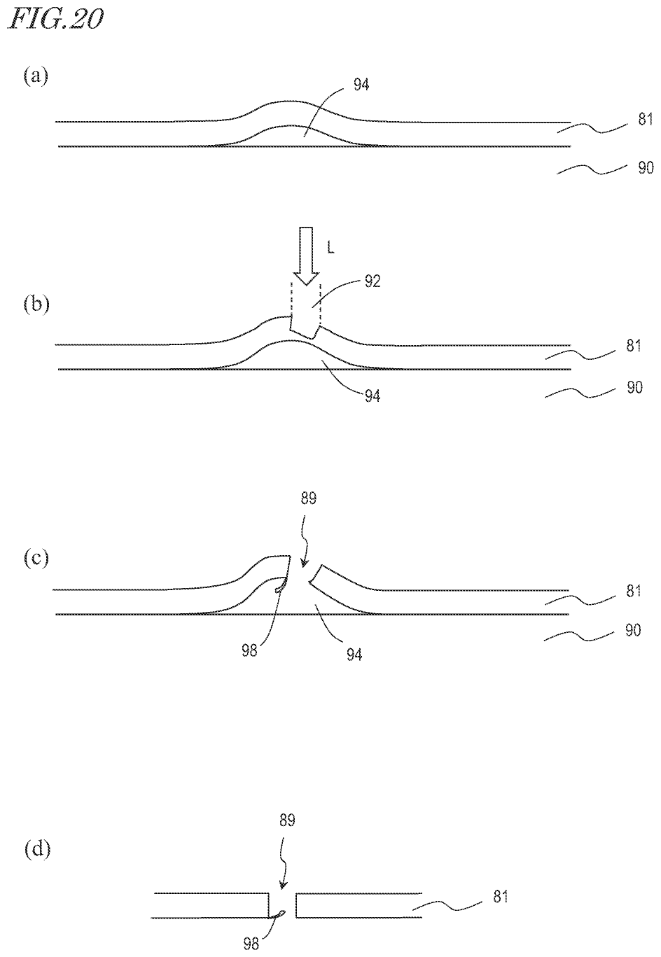

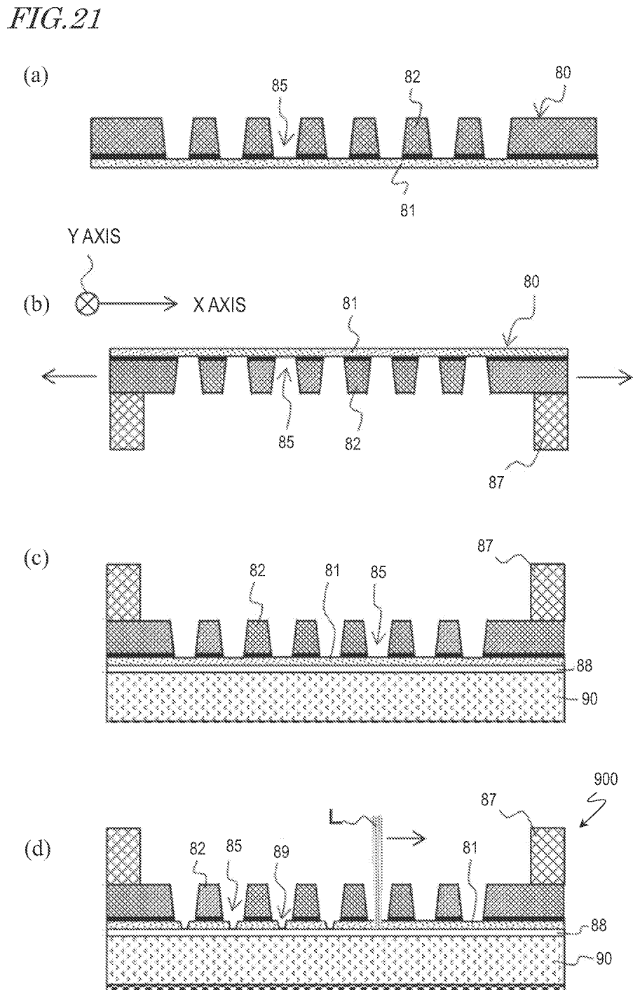

With a conventional method, as described above with reference to FIGS. 21(c) and 21(d), a laser beam L is irradiated onto a predetermined region of the resin film 81 (hereinafter, abbreviated as “laser irradiation region”) with the resin film 81 adhering to the glass substrate 90 by the surface tension of a liquid 88 such as ethanol, thereby forming an opening 89. Based on a study by the present inventors, it was found that with this method, when making the resin film 81 adhere to the glass substrate 90, bubbles may partially occur at the interface between the glass substrate 90 and the resin film 81, thereby locally lowering the adhesion. Moreover, the present inventors found that when there is a bubble under a certain laser irradiation region of the resin film 81, it not only makes it difficult to form the opening 89 with a high precision but also makes it likely that a burr is produced in that laser irradiation region. This will be described in detail with reference to FIG. 20.

FIGS. 20(a) to 20(d) are schematic cross-sectional views illustrating how a burr is produced because of a bubble between the glass substrate 90 and the resin film 81. FIG. 20 does not show the metal layer and the liquid.

As shown in FIG. 20(a), when the resin film 81 is made to adhere to a support member such as the glass substrate 90 (e.g., with a liquid therebetween), a gap (bubble) 94 may partially occur between the glass substrate 90 and the resin film 81. When the processing of the resin film 81 using a laser ablation method (hereinafter referred to simply as “laser processing”) is performed in this state, a laser irradiation region 92 for forming an opening may be placed in a portion of the resin film 81 that is located over the bubble 94, as shown in FIG. 20(b). The laser irradiation region 92 is subjected to a plurality of shots while focusing on the surface of the resin film 81, for example.

Laser ablation refers to a phenomenon in which when a laser beam is irradiated onto the surface of a solid, a constituent substance of the solid surface is rapidly released due to the energy of the laser beam. Herein, the speed of release is referred to as the ablation speed. In the laser processing, the ablation speed may be distributed depending on the energy distribution across the laser irradiation region 92 so that a through hole is formed first only in a portion of the resin film 81. Then, as shown in FIG. 20(c), another portion 98 of the resin film 81 that has been thinned is folded back onto the reverse side of the resin film 81 (i.e., into the bubble 94 between the resin film 81 and the glass substrate 90), and the portion 98 is no longer irradiated with the laser beam L. As a result, the opening 89 is formed with the thinned portion 98 remaining unremoved. In the present specification, the portion 98 of the resin film 81 that is thinned and left remaining is referred to as a “burr”.

With the burr 98 projecting on the reverse side of the resin film 81, when a vapor deposition mask is installed on a vapor deposition substrate, a portion of the vapor deposition mask may be lifted off the vapor deposition substrate. Then, there is a possibility that a vapor deposition pattern that is shaped corresponding to the opening 89 may not be obtained.

A process of removing the burr 98 from the resin film 81 (a burr removing step) may be performed after the laser processing. For example, attempts have been made to wipe the reverse surface of the resin film 81 (wiping). However, it is difficult, by a burr removing step, to entirely remove the burr 98 produced on the resin film 81. As illustrated in FIG. 20(d), if some burrs 98 return to be projecting into the inside of the opening 89 as a result of the wiping, a vapor deposition material may not be deposited in the vapor deposition step on a part of the region of the vapor deposition substrate that is defined by the opening 89 (this is referred to as a “film void”). As a result, electrodes are exposed, and there may possibly be a lighting defect due to short-circuiting.

Note that while a resin film has been described above as an example, it is believed that similar burrs will be produced if the laser processing is performed by a method similar to the method described above even with a film that is made of a material other than a resin.

<Deflection of Resin Film>

With a conventional layered mask, a resin film or a layered film of a resin film and a metal layer (a magnetic metal member) is secured to the frame while being pulled in a specific layer in-plane direction by a stretcher, or the like (hereinafter referred to as the “stretching step”). With such a mask, the resin film is likely to deflect due to its own weight. When deflection occurs, a gap may be formed between the vapor deposition mask and the vapor deposition substrate, thereby causing vapor deposition blur.

Particularly, this problem is pronounced if the opening of the magnetic metal member is large. For example, when an open mask is used as the magnetic metal member in order to more inexpensively and simply manufacture a vapor deposition mask, the opening of the open mask corresponds to a unit region (active area) U corresponding to one device and is relatively large. Therefore, the amount of deflection due to the own weight of the resin film is likely to increase.

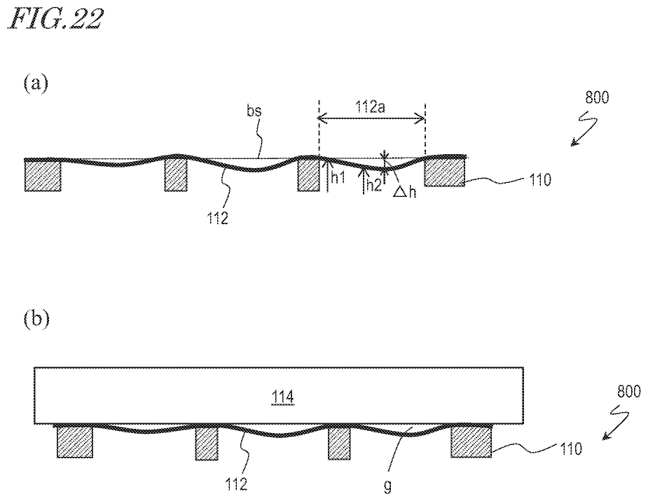

FIG. 22(a) is a cross-sectional view showing a vapor deposition mask 800 of a reference example. The vapor deposition mask 800 includes a magnetic metal member (e.g., an open mask) 110, and a resin film 112 attached to the magnetic metal member 110. A first region 112a of the resin film 112 that is located in the opening of the magnetic metal member 110 has a deflection (a portion indented in a concave shape). That is, when the vapor deposition mask 800 is installed so that the resin film 112 is facing up, the first region 112a of the resin film 112 is located below the reference surface bs, which includes the upper surface of the magnetic metal member 110. The amount of deflection Δh of the resin film 112 (the difference between the height h1 of the upper surface of the magnetic metal member 110 and the height h2 of the resin film 112) becomes maximum generally at the center of the first region 112a, for example.

When vapor deposition is performed, the vapor deposition mask 800 is secured to the vapor deposition substrate 114 by the magnetic force of the magnetic metal member 110 as shown in FIG. 22(b). At this point, if the resin film 112 has a deflection, a gap g is formed between the resin film 112 of the vapor deposition mask 800 and the vapor deposition substrate 114. Therefore, vapor deposition blur is likely to occur particularly in the vicinity of the center of the magnetic metal member 110, making it difficult to form a vapor deposition pattern that corresponds to the opening pattern formed in the first region 112a of the resin film 112.

As a result of examination based on the above findings, the present inventors found that by forming a resin layer on a support substrate such as a glass substrate and processing (forming an opening in) the resin layer on the support substrate, it is possible to realize high-precision processing while suppressing production of burrs and to reduce deflection depending on the formation condition of the resin layer (unpublished PCT/JP2017/003409 by the present applicant). The entire disclosure of PCT/JP2017/003409 is herein incorporated by reference.

After further examination, the present inventors arrived at a novel mask structure with which it is possible to more effectively suppress vapor deposition blur caused by deflection.

An embodiment of the present invention will now be described with reference to the drawings. Note that the present invention is not limited to the following embodiment.

### Embodiment

<Structure of Vapor Deposition Mask>

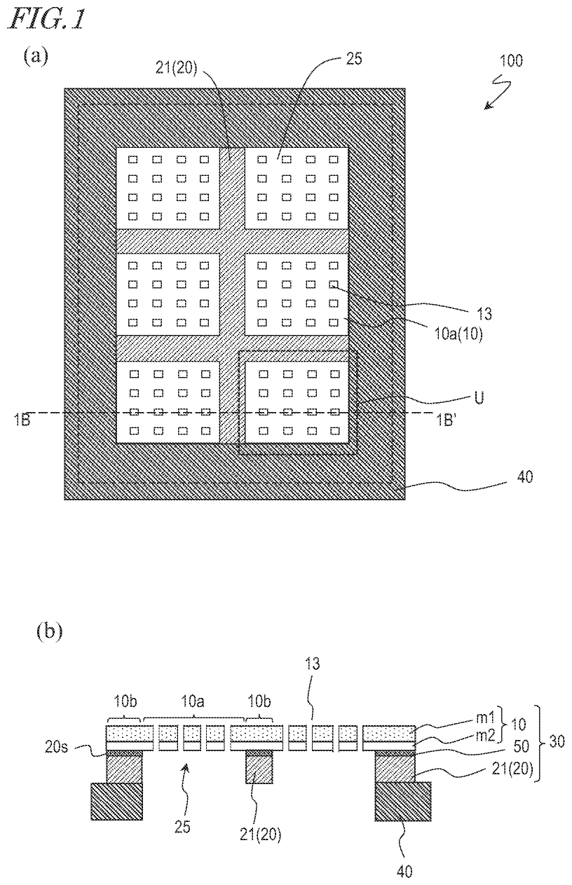

Referring to FIGS. 1(a) and 1(b), a vapor deposition mask 100 according to an embodiment of the present invention will be described. FIGS. 1(a) and 1(b) are a plan view and a cross-sectional view, respectively, schematically showing the vapor deposition mask 100. FIG. 1(b) shows a cross section taken along line 1B-1B′ of FIG. 1(a). Note that FIG. 1 schematically shows an example of the vapor deposition mask 100, and the size, number, arrangement, length ratio, etc., of the various components are not limited to those shown in the figure. This similarly applies also to other figures to be referred to below.

The vapor deposition mask 100 includes a magnetic metal member 20, a layered member 10 arranged on a primary surface 20s of the magnetic metal member 20. It may further include an adhesive layer 50 located at least partially between the layered member 10 and the magnetic metal member 20. The adhesive layer 50 is a layer that attaches together the layered member 10 and the magnetic metal member 20.

The vapor deposition mask 100 is a layered mask having a structure in which the layered member 10 and the magnetic metal member 20 are stacked together. Hereinafter, a structure 30 including the layered member 10 and the magnetic metal member 20 may be referred to as a “mask member”.

A frame 40 may be provided along the peripheral edge portion of the mask member 30. The frame 40 may be attached to a surface of the magnetic metal member 20 that is opposite from the primary surface 20s.

The magnetic metal member 20 includes at least one opening (hereinafter referred to as a “first opening”) 25. In this example, the magnetic metal member 20 has a plurality of (six) first openings 25. A portion 21 of the magnetic metal member 20 located around the first openings 25 and where a metal exists (including a portion between adjacent first openings 25) is referred to as a “solid portion”. The magnetic metal member 20 may have an open mask structure. That is, it may have one opening for a unit region U corresponding to one device.

As will be described later, when performing a vapor deposition step using the vapor deposition mask 100, the vapor deposition mask 100 is arranged so that the magnetic metal member 20 is located on the vapor deposition source side and the layered member 10 on the work (vapor deposition object) side. Since the magnetic metal member 20 is a magnetic member, the vapor deposition mask 100 can be easily held and secured on the work in the vapor deposition step by using a magnetic chuck.

The layered member 10 is arranged on the primary surface 20a of the magnetic metal member 20 so as to cover the first openings 25. The layered member 10 includes a first layer m1 and a second layer m2 that is arranged between the first layer m1 and the magnetic metal member 20. Note that the layered member 10 may have a 3- or more layered structure. The structure of each layer will later be described in detail.

A region 10a of the layered member 10 that is located in the first opening 25 is referred to as the “first region”, and a region 10b thereof that overlaps the solid portion 21 of the magnetic metal member 20 as seen from a direction normal to the vapor deposition mask 100 is referred to as the “second region”.

A plurality of openings (hereinafter “second openings”) 13 are formed in the first region 10a of the layered member 10. The plurality of second openings 13 are formed with a size, shape and position corresponding to the vapor deposition pattern to be formed on the work. In this example, a plurality of second openings 13 are arranged in an array with a predetermined pitch in each unit region U. The interval between two adjacent unit regions U is typically larger than the interval between two adjacent second openings 13 in a unit region U. In this example, there is no magnetic metal on the first region 10a.

The second region 10b of the layered member 10 is attached to the area around the first opening 25 of the magnetic metal member 20 (the solid portion 21) with the adhesive layer 50 therebetween. There is no particular limitation on the adhesive layer 50, but the adhesive layer 50 may be a metal layer. For example, the layered member 10 may be attached to the magnetic metal member 20 by forming a metal layer, by plating, or the like, on the second region 10b of the layered member 10, and welding together the metal layer and the solid portion 21 of the magnetic metal member 20. Alternatively, the adhesive layer 50 may be formed from an adhesive. Note that it is only required that the layered member 10 be attached to the magnetic metal member 20 by the method shown above, and it may not be attached directly to the frame 40.

<Layered Member 10>

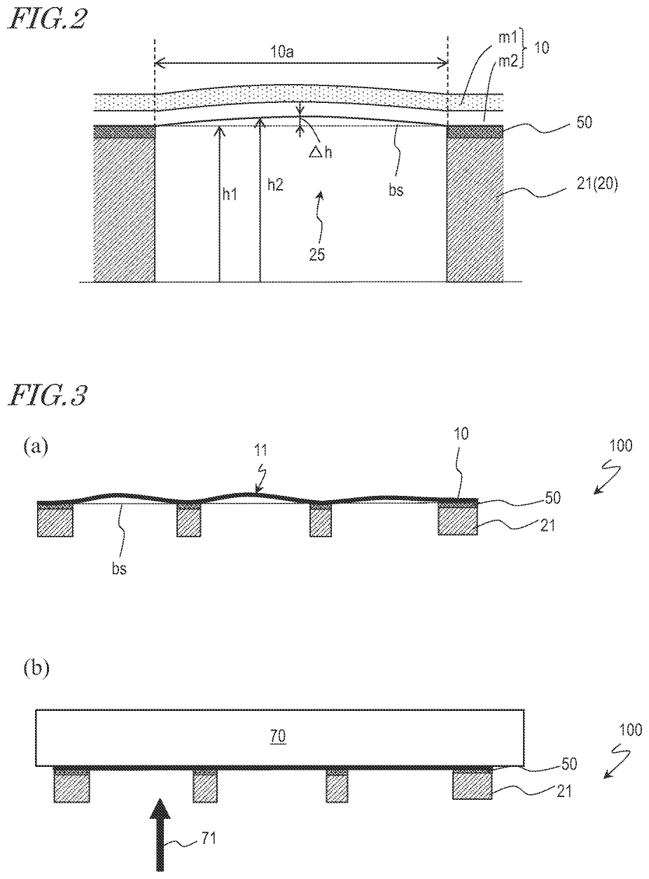

FIG. 2 is a schematic enlarged cross-sectional view of a portion of the layered member 10. Herein, a cross section of the layered member 10 is shown when the temperature of the vapor deposition mask 100 is a temperature (“first temperature”) T1 that is greater than or equal to room temperature. For example, the first temperature T1 is the temperature of vapor deposition mask in the vapor deposition step, and may be higher than room temperature. The first temperature T1 may be less than or equal to 60° C.

In the present embodiment, the layered member 10 includes the first layer m1 and the second layer m2 arranged on the magnetic metal member 20 side (the vapor deposition source side) of the first layer m1.

In each first opening 25 of the magnetic metal member 20, at the first temperature T1, the elastic modulus E1 of the first layer m1, the thickness a1 of the first layer m1, the internal stress σ1 of the first layer m1, the elastic modulus E2 of the second layer m2, the thickness a2 of the second layer m2, the internal stress σ2 of the second layer m2 (where σ1 and θ2 are positive for tensile stress) satisfy Expressions (1) and (2) below.

σ1/E1−σ2/E2<0 (1)

0<a1×σ1+a2×σ2 (2)

Expression (2) indicates that the first region 10a of the layered member 10 including the first layer m1 and the second layer m2 has a tensile stress (a tensile internal stress) in the layer in-plane direction as a whole. As the first region 10a of the layered member 10 has a tensile stress, it is possible to at least reduce the deflection caused by the own weight in the first region 10a of the layered member 10.

Expression (1) indicates that in the first region 10a, the amount of distortion in the direction of the tensile stress of the second layer m2 is greater than the amount of distortion in the direction of the tensile stress of the first layer m1 (i.e., the second layer m2 has a higher shrinkage).

As each layer of the layered member 10 satisfies Expressions (1) and (2), each first region 10a of the layered member 10 warps so as to protrude toward the first layer m1 at the first temperature T1, as shown in FIG. 2. In other words, the first region 10a of the layered member 10 warps in a protruding shape (protruding upward) when the vapor deposition mask 100 is arranged so that the layered member 10 is located over the magnetic metal member 20. Where the surface bs, which includes the junction surface between the lower surface of the layered member 10 and the magnetic metal member 20, is the reference surface, the height h2 of the lower surface of the layered member 10 may be greater than or equal to the height h1 of the reference surface ba across the entire first region 10a. The difference Δh (=h2−h1>0) between the height h2 of the lower surface of the layered member 10 and the height h1 of the reference surface ba may be at maximum in the vicinity of the center of the first region 10a.

As an example, by controlling the thermal stress of the first layer m1 and the second layer m2, it is possible to form the layered member 10 that is warped so as to protrude toward the first layer m1 (in a protruding surface shape). This will be described below with reference to the drawings.

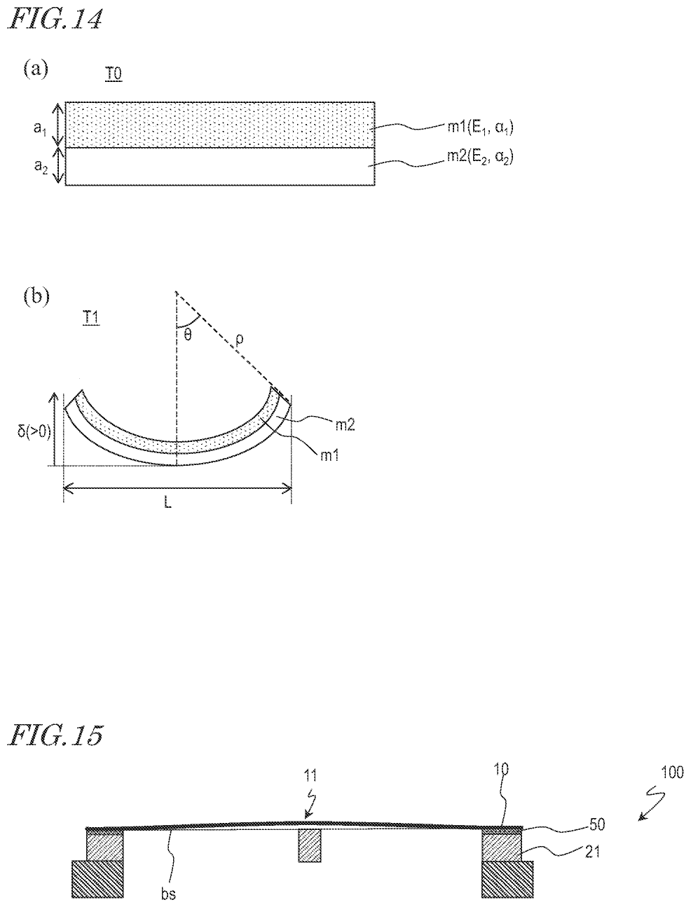

FIG. 14(a) and FIG. 14(b) views schematically showing the layered member 10 at the temperature T0 and the temperature T1. The temperature T0 is the temperature at the time of formation of the layered member, i.e., the temperature when the two layers m1 and m2 are attached/secured together at the interface. Note however that where a resin layer is used in the layered member 10, it is believed that the stress is relaxed at the glass transition temperature thereof. Therefore, the glass transition temperature Tg may be considered the temperature T0. The temperature (first temperature) T1 is the temperature at the time of vapor deposition, i.e., the temperature of the vapor deposition mask 100 when vapor deposition is done by using the vapor deposition mask 100. The amount of displacement δ at the edge of the layered member 10 for a temperature change is considered the amount of warp. Herein, the amount of warp δ when the layered member 10 warps so as to protrude toward the second layer m2 is considered positive. When the layered member 10 warps so as to protrude toward the first layer m1, the amount of warp b takes a negative value. The amount of warp δ can be calculated as follows using the theoretical formula of bimetal warp.

According to the Timoshenko theory, the theoretical formula of bimetal warp is represented by Expressions (3) and (4) shown below.

$$\begin{matrix}[ Exp . 3 ] & \\ \frac{1}{ρ} = \frac{6 ( α 2 - α 1 ) ( T 1 - T 0 ) {( 1 + m )}^{2}}{h [ 3 {( 1 + m )}^{2} + ( 1 + mn ) [ {m}^{2} + {( mn )}^{- 1} ] ]} & ( 3 ) \\ [ Exp . 4 ] & \\ δ = ρ ( 1 - cos θ ) = \frac{{L}^{2}}{8} \frac{1}{ρ} & ( 4 )\end{matrix}$$

where E1 and E2 are the elastic moduli of the first layer m1 and the second layer m2, a1 and a2 are the thicknesses of the first layer m1 and the second layer m2, α1 and α2 are the linear expansion coefficients α of the first layer m1 and the second layer m2. h, m and n are h=a1+a2, m=a1/a2 and n=E1/E2, respectively. L corresponds to the width of the layered member 10 (the width of the first opening 25 of the magnetic metal member 20). ρ is the curvature of the layered member 10, and θ is a half of the central angle to an arc when the warp of the layered member 10 is assumed to be an arc. Consider an arc of radius ρ, and let the length of the chord be L. Where a vertical line is drawn from the center so as to pass through the center of the chord, the amount of warp δ is the length between the center of the chord and the intersection with the vertical line of the arc.

(α2−α1) (T1−T0) in Expression (3) can be represented as Expression (5) below using the internal stresses σ1 and σ2 below.

σ1=−a1×(T1−T0)×E1

σ2=−a2×(T1−T0)×E2

where the internal stresses σ1 and σ2 are thermal stresses that occur in the respective layers when the temperature changes from T0 to T1. The sign of the stress is positive for tensile and negative for compressive in each layer.

σ1/E1−σ2/E2 (5)

When Expression (5) is negative (i.e., when Expression (2) σ1/E1−σ2/E2<0 is satisfied), the curvature p calculated from Expression (3) is negative, and the amount of warp δ obtained from Expression (4) is also negative. Therefore, when Expression (2) is satisfied, the layered member 10 warps so as to protrude toward the first layer m1 (δ<0).

Note that the description above illustrates an example where the internal stresses σ1 and σ2 are both caused by thermal stress, but the internal stress of a film typically includes not only thermal stress but also internal stress (tensile stress) due to curing shrinkage when the film is made of a curable resin, for example. With an inorganic film, compressive stress or tensile stress occurs at the time of film deposition depending on the film deposition conditions (e.g., CVD conditions).

According to the present embodiment, the layered member 10 has a warp such as to protrude toward the vapor deposition substrate, and it is therefore possible to make the vapor deposition mask 100 adhere to the vapor deposition substrate at the time of vapor deposition. Therefore, it is possible to suppress the vapor deposition blur caused by the gap g between the vapor deposition mask and the vapor deposition substrate as described above with reference to FIGS. 22(a) and 22(b).

FIG. 3(a) is a schematic cross-sectional view of the vapor deposition mask 100 of the present embodiment, and FIG. 3(b) is a cross-sectional view illustrating the vapor deposition step using the vapor deposition mask 100.

As shown in FIG. 3(a), the layered member 10 of the vapor deposition mask 100 has a warp 11 such as to protrude toward the vapor deposition substrate due to the internal stress difference between the first layer m1 and the second layer m2. Therefore, when vapor deposition is performed on the vapor deposition substrate 70 from the direction (vapor deposition direction) 71, as shown in FIG. 3(b), if the vapor deposition mask 100 is made to adhere to the vapor deposition substrate 70 by the magnetic metal member 20, the warp 11 in a protruding surface shape of the layered member 10 is pressed against the vapor deposition substrate 70 so that no gap is formed between the vapor deposition substrate 70 and the layered member 10 (or the gap can be reduced therebetween). Therefore, it is possible to suppress the vapor deposition blur and to realize an intended vapor deposition pattern.

According to the present embodiment, there is no need to separately arrange a magnetic metal on the first region 10a of the layered member 10 in order to suppress misalignment of the vapor deposition pattern caused by deflection. This eliminates the need for a precise metal film patterning step, and it is possible to significantly reduce the manufacturing process and the manufacturing cost as compared with conventional methods.

As will be described below, in the present embodiment, the layered member 10 is formed in the order of the first layer m1 and the second layer m2 on a support substrate such as a glass substrate. Thereafter, the second openings 13 may be formed by performing the laser processing on the layered member 10 on the support substrate. The support substrate and the layered member 10 adhere to each other with no (or little) bubble therebetween, thereby suppressing the occurrence of burrs in the laser processing step on the layered member 10. Therefore, the number of burrs (per unit area) occurring in the vicinity of the second openings 13 can be significantly reduced as compared with conventional methods. The support substrate is removed from the layered member 10 after the second openings 13 are formed in the layered member 10. When this method is used, a layer that can be removed the support substrate by a laser lift-off method, or the like, is used as the first layer m1.

There is no particular limitation on the material, thickness, etc., of the first layer m1 and the second layer m2, as long as Expressions (1) and (2) above are satisfied.

The material of the first layer m1 and the second layer m2 may be an organic material or an inorganic material. Note however that when the second openings 13 are formed in the layered member 10 by laser processing, a material that can be subjected to laser processing is used as the material of the first layer m1 and the second layer m2.

The material of the first layer m1 may be a resin material such as polyimide, polyolefin, fluoropolymer, acrylic resin and epoxy resin, an inorganic material (excluding metal materials) such as graphite, molybdenum silicide film, silicon nitride film, silicon oxide film, graphite, molybdenum silicide film, titanium oxide, aluminum oxide, zinc oxide, indium oxide, tin oxide and ITO or silicon oxide, zinc oxide, indium oxide, tin oxide and ITO that are coated by a sol-gel method or a polysilazane method, or a metal material such as nickel, invar alloy and super invar alloy. It may be an organic-inorganic composite material such as silsesquioxane. The material of the second layer m2 may be a resin material such as polyimide, polyolefin, fluoropolymer, acrylic resin and epoxy resin, an inorganic material (excluding metal materials) such as graphite, molybdenum silicide film, silicon nitride film, silicon oxide film, titanium oxide, aluminum oxide, zinc oxide, indium oxide, tin oxide and ITO or silicon oxide, zinc oxide, indium oxide, tin oxide and ITO that are coated by a sol-gel method or a polysilazane method, or a metal material such as nickel and invar alloy. It may be an organic-inorganic composite material such as silsesquioxane. A resin material such as acrylic resin and epoxy resin may be a thermosetting material or an actinically-curable material that is cured by using actinic ray such as ultraviolet ray (UV) or electron beam (EB).

There is also no particular limitation on the method for forming the first layer m1 and the second layer m2. It may be formed on a support substrate using a known film deposition method such as a coating method, a CVD method, a plasma CVD method or a sputtering method. The method for forming the first layer m1 and the formation conditions therefor, such as the formation temperature, may be the same as or different from the method for forming the second layer m2 and the formation conditions therefor.

One or both of the first layer m1 and the second layer m2 may be a resin layer. The material of the resin layer may suitably be polyimide, for example. Polyimide has good strength, chemical resistance, and heat resistance. The material of the resin layer may be any other resin material such as polyparaxylene, bismaleimide and silica hybrid polyimide. The in-plane linear thermal expansion coefficient of the resin layer (hereinafter abbreviated as “thermal expansion coefficient”) αR (ppm/° C.) is preferably about the same as the thermal expansion coefficient of the substrate to be the vapor deposition object. Such a resin layer can be formed based on the formation conditions such as the resin material and the baking condition.

The resin layer may be a layer that is formed by applying a solution containing a resin material (e.g., a soluble polyimide solution) or a solution containing a precursor of a resin material (e.g., a polyimide varnish) onto a support substrate and performing a heat treatment. The heat treatment as used herein includes a solvent removing step (e.g., 100° C. or higher) when using a soluble polyimide solution, or a heat treatment to perform a prebake and bake (thermosetting) step (e.g., 300° C. or higher) when using a polyimide varnish. The resin layer formed as described above may have a tensile stress (tensile internal stress) in the layer in-plane direction (i.e., σ>0). The tensile stress of the resin layer can be controlled by the heat treatment condition, or the like, used when forming the resin layer on the support substrate, for example. The thickness of the resin layer formed by the method described above may be 3 μm or more, for example. Thus, it is possible to obtain a resin layer having a more uniform thickness.

Typically, when forming a resin layer on the support substrate by a heat treatment, the heat treatment is performed under such conditions that the residual stress on the resin layer can be reduced as much as possible. This is because an increase in the residual stress (tensile stress) on the resin layer will cause problems such as warping of the support substrate, thereby lowering the shape stability and the reliability. In contrast, the present embodiment intentionally causes a predetermined tensile stress on the resin layer, thereby causing the layered member 10 including the resin layer to warp in a protruding shape in a predetermined direction.

The first layer m1 and the second layer m2 may be formed from the same material. For example, polyimide layers having different internal stresses may be formed, as the first layer m1 and the second layer m2, by varying the temperature condition.

A polyimide layer may be formed as the first layer m1 and a resin layer may be formed as the second layer m2 using an actinically-curable resin material that is cured using actinic ray such as ultraviolet ray (UV) or electron beam (EB). The use of an actinically-curable resin material is advantageous in that a stress can be applied to the second layer m2 without using heat, thus avoiding changes in the internal stress of the first layer m1 due to heat.

When a UV-curable acrylic resin material is used, the internal stress of the acrylic resin layer can be controlled by, for example, adjusting the average (meth)acrylic equivalent (=molecular weight/the number of (meth)acryloyl groups) of the UV-curable acrylic monomer used (see “Internal Stress Control of the UV Cured Inkjet Ink Film, Ricoh Technical Report, January 2014, No. 39, p. 139-145”).

An inorganic material layer may be formed as the first layer m1 and/or the second layer m2. For example, a resin layer such as a polyimide layer may be formed as the first layer m1, and an inorganic material layer (such as a titanium oxide layer) may be formed as the second layer m2 by a sputtering method, or the like.

The internal stress of the inorganic material layer may be controlled by the composition of the inorganic material, the method for forming the inorganic material layer and the formation conditions therefor. For example, the lower the density of the titanium dioxide layer, the more tensile stress it is likely to have. According to “Special issue, Chemical thin film; Optimization of mechanical characteristic of thin film and optical thin film material, O plus E, August 2008, vol. 30, No. 8, p. 1-7”, it is possible to obtain a titanium oxide layer that has a low density and exhibits a tensile stress (greater than 0 and less than 0.5 GPa) by using an electron beam vapor deposition method, for example.

When a silicon nitride layer is formed as an inorganic material layer, the thermophysical property values of the silicon nitride layer vary because the composition ratio and the impurity content vary depending on the method for forming the silicon nitride layer. In “Toyota Central R&D Labs., Inc., R&D review, March 1993, vol. 34, No. 1, p. 19-24,” the composition, the elastic modulus, the thermal expansion coefficient, etc., of the silicon nitride layer when formed by a sputtering method, an LPCVD method and a plasma CVD method, are described. Furthermore, when the silicon nitride layer is formed by a CVD method, the stress generated in the silicon nitride layer can be increased in the positive direction (the direction in which the tensile stress increases) by increasing the ratio of Si in the material gas (increasing the SiH₂Cl₂/NH₃ ratio) or by increasing the film deposition temperature. As an example, if the film deposition temperature is set to about 854° C. and the material gas ratio SiH₂Cl₂:NH₃ is set to 5:1, the internal stress σ of the silicon nitride layer will be about 60 MPa.

The first layer m1 and/or the second layer m2 may be a metal layer. The metal layer can be formed, for example, on the support substrate by a sputtering method, electrolytic plating, electroless plating, or the like. For example, a super invar alloy film as the first layer m1 and an invar alloy film as the second layer m2 may be formed on the support substrate (e.g., a quartz glass substrate) by electroless plating.

Note that the first layer m1 and the second layer m2 of the layered member 10 being on the support substrate may each have a stress distribution, but once the support substrate is removed, the magnitudes of tensile stress on the layers m1 and m2 of the layered member 10 can be leveled to be substantially uniform across the surface. Thus, a tensile stress of a substantially constant magnitude can be realized across the first region 10a of the layered member 10.

There is no particular limitation on the thickness of the layered member 10 (in this example, the total thickness of the first layer m1 and the second layer m2). Note however that if the layered member 10 is too thick, a portion of the vapor deposition film may be formed to be thinner than the intended thickness (this is called “shadowing”). In order to suppress the occurrence of shadowing, the thickness of the layered member 10 is preferably 25 μm or less, although it depends on the taper angle of the second openings 13. Also in view of the strength and the cleaning tolerance of the layered member 10 itself, it is preferred that the thickness of the layered member 10 is 3 μm or more.

<Magnetic Metal Member 20>

The present embodiment is particularly advantageous when using the magnetic metal member 20 having the first openings 25 of a relatively large size therein, such as an open mask, for example. The width (the dimension along the width direction) of the first opening 25 may be 30 mm or more or may be 50 mm or more, for example. There is no particular limitation on the upper limit of the width of the first opening 25, it may be 300 mm or less, for example. Even when the size of the first openings 25 is relatively large, it is possible to reduce the deflection occurring in the layered member 10 because of the internal tensile stress of the layered member 10.

In the present embodiment, the magnetic metal member 20 receives a compressive stress in an in-plane direction from the layered member 10. Note that when a layered film is secured on a frame by a stretching step, the metal film and the resin film both receive tension in an in-plane direction from the frame, and a configuration in which the resin film gives a compressive stress on the metal film is not obtained. Also when only the resin film is secured on the frame by a stretching step, the resin film is not adhering to the metal film, and it is believed that the metal film does not receive a compressive stress from the resin film.

Various magnetic metal materials can be used as the material of the magnetic metal member 20. Materials having a relatively large thermal expansion coefficient αM such as Ni, Cr, ferritic stainless steel and martensitic stainless steel, for example, may be used, or materials having a relatively small thermal expansion coefficient αM such as an Fe—Ni-based alloy (invar) or an Fe—Ni—Co-based alloy, for example, may be used.

There is no particular limitation on the thickness of the magnetic metal member 20. Note however that when the magnetic metal member 20 is too thin, the attraction force received for the magnetic field of the magnetic chuck will decrease, and it will be difficult to hold the vapor deposition mask 100 on the work in the vapor deposition step. Therefore, it is preferred that the thickness of the magnetic metal member 20 is 5 μm or more.

It is preferred that the thickness of the magnetic metal member 20 is set within such a range that no shadowing occurs in the vapor deposition step. With conventional vapor deposition masks, a metal layer, which is a hold member, was arranged close to the openings of the resin film. Therefore, the thickness of the metal layer needed to be small (e.g., 20 μm or less) in order to suppress shadowing in the vapor deposition step. In contrast, according to the present embodiment, the layered member 10 has a predetermined tensile stress, and there is no need to arrange the magnetic metal member 20 close to the second openings 13 of the layered member 10. Therefore, the edge portion of the first opening 25 of the magnetic metal member 20 can be arranged sufficiently apart from the second openings 13 of the layered member 10 (e.g., the minimum distance Dmin between the solid portion 21 of the magnetic metal member 20 and the second openings 13 is 1 mm or more). When the minimum distance Dmin is large, shadowing is unlikely to occur even if the magnetic metal member 20 is made thicker, thereby allowing the magnetic metal member 20 to be made thicker as compared with conventional methods. The thickness of the magnetic metal member 20 may be 1000 μm or more, for example, although it also depends on the vapor deposition angle, the taper angle of the magnetic metal member 20, and the minimum distance Dmin between the solid portion 21 of the magnetic metal member 20 and the second openings 13. When an open mask is used as the magnetic metal member 20, the thickness of the open mask can be set to 300 μm or more, for example, by designing the open mask so that the size of the first opening 25 is sufficiently larger than the unit region U. While there is no particular limitation on the upper limit value of the thickness of the magnetic metal member 20, it is possible to suppress shadowing if it is 1.5 mm or less, for example. Thus, according to the present embodiment, it is possible to increase the degree of freedom in selecting the thickness, as well as the material of the magnetic metal member 20.

<Frame 40>

The frame 40 is formed from a magnetic metal, for example. Alternatively, it may be formed from a non-metal material, e.g., a resin (plastic). With conventional vapor deposition masks, the frame was required to have an adequate rigidity so that the frame would not be deformed or broken by the tension from the layered film (a resin film and a metal film) secured on the frame due to the stretching step. Therefore, a frame made of an invar having a thickness of 20 mm, for example, was used. In contrast, according to the present embodiment, since the frame 40 is attached without performing the stretching step or without applying a large tension on the magnetic metal member 20, there is no tension on the frame 40 due to the stretching step. Therefore, it is possible to use a frame 40 having a lower rigidity as compared with conventional methods, increasing the degree of freedom in selecting the material of the frame 40. It is also possible to make the frame 40 thinner as compared with conventional methods. Using a frame that is thinner as compared with conventional methods or using a frame made of a resin, it is possible to obtain the vapor deposition mask 10 that has a light weight and a good handling property.

<Method for Manufacturing Vapor Deposition Mask>

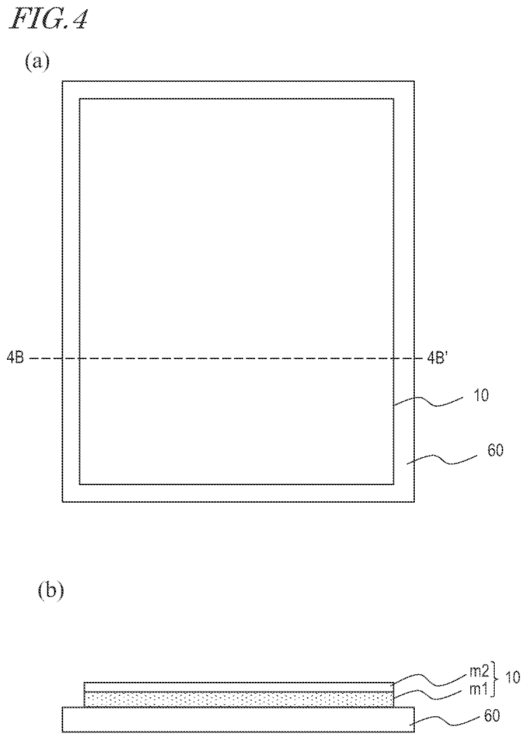

Referring to FIG. 4 to FIG. 8, a method for manufacturing a vapor deposition mask of the present embodiment will be described by using a method for manufacturing the vapor deposition mask 100 as an example. FIGS. 4(a) and 4(b) to FIGS. 8(a) and 8(b) are a process plan view and a process cross-sectional view, respectively, showing an example of a method for manufacturing the vapor deposition mask 100.

First, as shown in FIGS. 4(a) and 4(b), a support substrate 60 is provided, and the first layer m1 and the second layer m2 are formed in this order on the support substrate 60. For example, a glass substrate may suitably be used as the support substrate 60. There is no particular limitation on the size and thickness of the glass substrate. Note however that the thermal expansion coefficient of the support substrate 60 is preferably less than or equal to the thermal expansion coefficient of the first layer m1 of the layered member 10. The thermal expansion coefficient of the support substrate 60 may be smaller than the thermal expansion coefficient of each layer of the layered member 10. For example, if the thermal expansion coefficient of each layer of the layered member 10 is greater than or equal to 3.8 ppm/° C., a non-alkali glass substrate may suitably be used as the support substrate 60. If the thermal expansion coefficient of each layer of the layered member 10 is smaller than 3.8 ppm/° C., a substrate having an even smaller thermal expansion coefficient, such as a quartz glass substrate, may be used as the support substrate 60.

Herein, an example of forming a polyimide layer as the first layer m1 and an acrylic resin layer as the second layer m2 will be described. The materials of the layers m1 and m2 are not limited to this example.

First, a solution containing a precursor of the resin material (e.g., a polyimide varnish) or a solution containing the resin material (e.g., a soluble polyimide solution) is applied to the support substrate 60. A known method such as a spin coat method and a slit coater method can be used as a solution application method. Herein, polyimide is used as the resin material, and a solution containing polyamic acid, which is a precursor of polyimide (a polyimide varnish), is applied to the support substrate 60 by the spin coat method. Then, a polyimide layer is formed by performing a heat treatment (baking). The heat treatment temperature may be set to be 300° C. or more, e.g., 400° C. or more and 500° C. or less.

The heat treatment conditions are set so as to produce a predetermined tensile stress on the polyimide layer. For example, they may be set to produce a tensile stress greater than 0.2 MPa (preferably 3 MPa or more). The magnitude of the tensile stress may vary depending on the material of the polyimide layer and the heat treatment conditions, as well as, for example, the thickness, shape, and size of the support substrate 60, and the material properties (Young's modulus, Poisson's ratio, thermal expansion coefficient, etc.) of the support substrate 60. The heat treatment conditions as used herein include the heat treatment temperature (maximum temperature), the temperature increase rate, the holding time at a high temperature (e.g., 300° C. or higher), the atmosphere during the heat treatment, etc. Not only the temperature profile while heating but also the temperature profile while cooling are also included.

In order to increase the tensile stress remaining in the polyimide layer, for example, the conditions may be set such that the polyimide varnish is rapidly imidized. As an example, it is possible to increase the tensile stress by increasing the temperature increase rate. For example, when a polyimide layer is formed on a glass substrate by a heat treatment, a glass substrate with a polyimide varnish applied thereon may be heated to a temperature of 300° C. or more and 600° C. or less at a rate of 30° C./min or more. Throughout the entire heat treatment process including the heating and cooling, if the total time for which the glass substrate is held at a temperature of 300° C. or more, for example, is set to be short (e.g., within 30 min), it is possible to increase the tensile stress remaining in the polyimide layer. Moreover, it is possible to increase the tensile stress also by setting the entire heat treatment time including the heating and cooling to be relatively short (e.g., within 1 hour), setting the holding time (leave time) at the maximum temperature to be short (e.g., within 5 min), and rapidly cooling after reaching the maximum temperature. There is no particular limitation on the heat treatment atmosphere, which may be an atmospheric atmosphere or a nitrogen gas atmosphere, but the temperature increase rate can be increased more easily if a heat treatment is performed under a depressurized atmosphere of 100 Pa or less.

Instead of a polyimide varnish, a solution containing a solvent-soluble polyimide (polymer) (a soluble polyimide solution) may be applied to the support substrate 60 and the solvent may be removed (baked) to form a polyimide layer. The bake temperature can be selected suitably depending on the boiling point of the solvent and there is no particular limitation thereon, but it is 100° C. to 320° C., preferably 120° C. to 250° C., for example. Even in this case, it is possible to increase the tensile stress remaining in the polyimide layer by increasing the temperature increase rate to about the same level as described above or by shortening the holding time at a high temperature.

Then, the second layer m2 is formed on the polyimide layer using a UV-curable acrylic resin material. The acrylic resin layer can be formed by, for example, applying a UV-curable resin composition containing a UV-curable acrylic monomer or oligomer, a polymerization initiator, or the like, to the first layer m1, heating (e.g., 60° C.) and volatilizing the solvent contained in the composition, and then curing the composition by UV irradiation. Thus, the layered member 10 including the first layer m1 and the second layer m2 is obtained.

When the layered member 10 is formed on the support substrate 60, the support substrate 60 may warp depending on the material and the thickness of the support substrate 60. The layered member 10 has a stress distribution on the support substrate 60. For example, the tensile stress increases from the center to the edge of the layered member 10. A greater tensile stress may occur in the direction in which the length of the support substrate 60 is greater.

Next, as shown in FIGS. 5(a) and 5(b), the adhesive layer 50 is formed on a portion of the layered member 10. The adhesive layer 50 has openings 55 corresponding to the first openings 25 of the magnetic metal member 20 to be described below. The adhesive layer 50 may be formed over the entire region (the region to be the second region 10b) of the layered member 10 that corresponds to the solid portion 21 of the magnetic metal member 20, or over a portion thereof. Preferably, it is arranged so as to surround the portion of the layered member 10 that is to be the first region 10a.

The adhesive layer 50 may be a metal layer or may be formed from an adhesive. There is no limitation as long as the adhesive layer 50 is secured to the upper surface of the layered member 10. For example, a metal layer may be formed as the adhesive layer 50 by a method such as electroplating or electroless plating. Various metal materials can be used as the material of the metal layer, and Ni, Cu, Sn, Co and Fe can be suitably used, for example. There is no limitation on the thickness of the metal layer as long as it is large enough to withstand the process of welding to the magnetic metal member 20 to be described below, and it is 1 μm or more and 100 μm or less, for example.

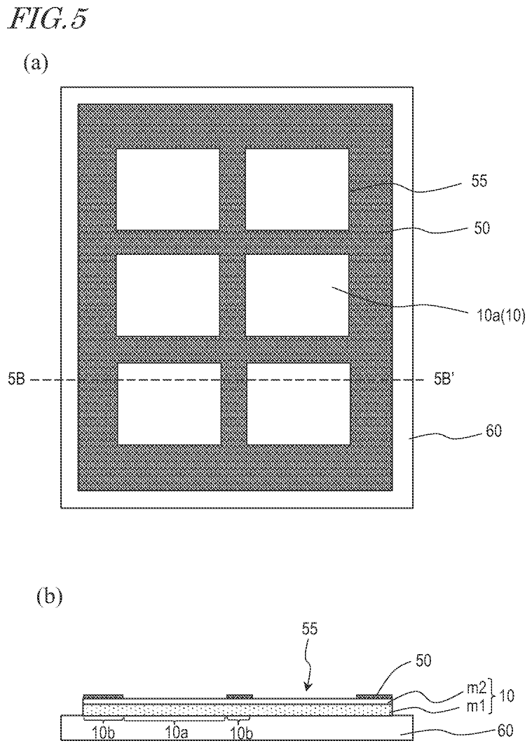

Next, as shown in FIGS. 6(a) and 6(b), the layered member 10 formed on the support substrate 60 is secured on the magnetic metal member 20 so as to cover the first openings 25. The layered member 10 and the magnetic metal member 20 are attached together with the adhesive layer 50 therebetween. The region 10a of the layered member 10 that is located in the first opening 25 of the magnetic metal member 20 is to be the first region, and the region 10b thereof that overlaps with the solid portion 21 is to be the second region.

The magnetic metal member 20 is formed from a magnetic metal material, and has at least one first opening 25. There is no particular limitation on the method for manufacturing the magnetic metal member 20. For example, it can be manufactured by providing a magnetic metal plate, forming an etching mask with a photoresist by a photolithography process, and forming the first openings 25 in the magnetic metal plate by a wet etching method. For example, an invar (an Fe—Ni-based alloy containing about 36 wt % of Ni) can be suitably used as the material of the magnetic metal member 20.

When the adhesive layer 50 is a metal layer, a laser beam may be irradiated from the layered member 10 side, thereby welding the adhesive layer 50 to the magnetic metal member 20. In this process, spot welding may be performed at a plurality of spots with intervals therebetween. The number of spots to be spot-welded and the intervals (pitch) therebetween may be selected suitably. Thus, the layered member 10 is attached to the magnetic metal member 20 with the adhesive layer 50 therebetween.

Note that the adhesive layer 50 does not need to be a metal layer. The layered member 10 and the magnetic metal member 20 may be attached together using the adhesive layer 50 formed from an adhesive (dry lamination or thermal lamination).

It is preferred that the adhesive layer 50 is not formed on a portion of the layered member 10 that is to be the first region 10a. If the adhesive layer 50 is formed in the first region 10a, the tensile stress of the layered member 10 may have an in-plane distribution in the first region 10a even after the support substrate 60 is removed from the layered member 10 in a later step.

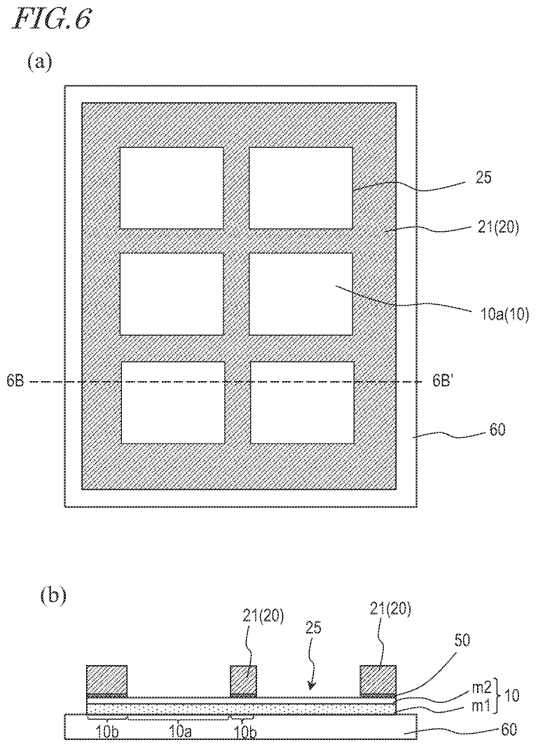

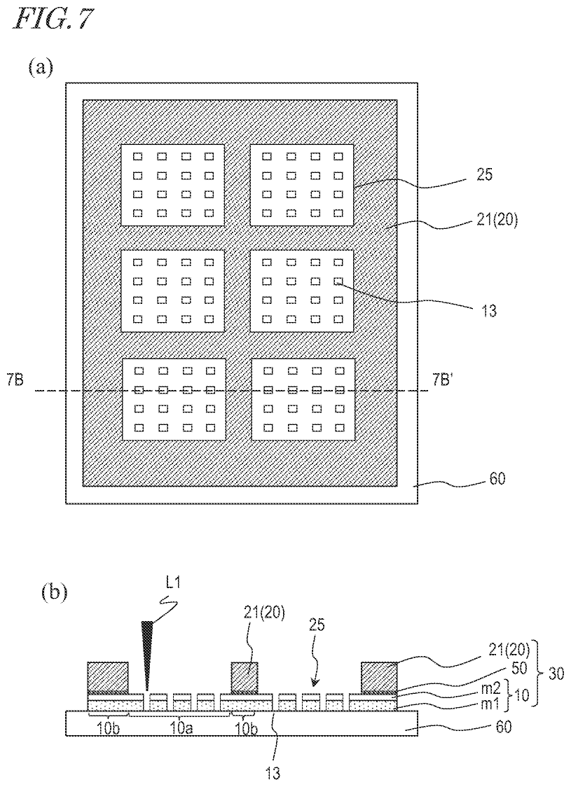

Next, as shown in FIG. 7(a) and FIG. 7(b), a plurality of second openings 13 are formed in the first region 10a of the layered member 10 by a laser ablation method (a laser processing step), for example. Thus, the mask member 30 including the magnetic metal member 20 and the layered member 10 is obtained.

A pulsed laser is used for the laser processing of the layered member 10. Herein, a YAG laser is used, and the laser beam L1 having a wavelength of 355 nm (the third harmonic) is irradiated onto a predetermined region of the layered member 10. The energy density of the laser beam L1 is set to 0.36 J/cm², for example. As described above, the laser processing of the layered member 10 is performed in a plurality of shots while focusing the laser beam L1 on the surface of the layered member 10. The shot frequency is set to 60 Hz, for example. The conditions of the laser processing (the wavelength of the laser beam, the irradiation conditions, etc.) are not limited to those described above, and are selected suitably so that it is possible to process the layered member 10.

In the present embodiment, laser processing is performed on the layered member 10 formed on the support substrate 60. Since there is no bubble between the support substrate 60 and the layered member 10, it is possible to form the second openings 13 of an intended size with a higher precision than that of conventional methods, and it is possible to suppress the production of burrs (see FIG. 20).

Then, as shown in FIG. 8(a) and FIG. 8(b), the mask member 30 is removed from the support substrate 60. The removing of the support substrate 60 can be performed by a laser lift-off method, for example. When the adhesion force between the layered member 10 and the support substrate 60 is relatively weak, the removing may be done mechanically using a knife edge, or the like.

Herein, the layered member 10 is removed from the support substrate 60 by irradiating a laser beam (wavelength: 308 nm) from the support substrate 60 side using an XeCl excimer laser, for example. Note that there is no limitation on the laser beam as long as it has a wavelength that passes through the support substrate 60 and is absorbed by the layered member 10, and other excimer lasers or high power lasers such as YAG lasers may be used.

Note that when removing the support substrate 60 by using a laser lift-off method, in the step shown in FIG. 4(a), an amorphous silicon layer or a high-melting-point metal layer such as tungsten (W) may be first formed on the support substrate 60 as a removal (a sacrificial layer), and then the first layer m1 may be formed on the removal layer. Note that if a removal layer is provided between the support substrate 60 and the first layer m1, the support substrate 60 can be more easily removed by laser irradiation. Therefore, the laser power required for laser lift-off can be lowered, thereby reducing damage to the first layer m1 by laser irradiation.

When the support substrate 60 is removed, the layered member 10 is stretched without slack (taut) due to the inherent tensile stress. The magnitude of the tensile stress in a predetermined direction can be averaged in a portion of the layered member 10 that is not attached to the magnetic metal member 20 (herein, the first region 10a).

Thereafter, although not shown in the figure, the frame 40 is secured to the mask member 30 (the frame attachment step). The vapor deposition mask 100 shown in FIG. 1 is manufactured as described above.

In the frame attachment step, the frame 40 is mounted on the peripheral portion of the magnetic metal member 20, and the peripheral portion of the magnetic metal member 20 and the frame 40 are attached together. The frame 40 is made of a magnetic metal such as invar, for example. The peripheral portion of the magnetic metal member 20 and the frame 40 may be welded together by irradiating a laser beam from the layered member 10 side (spot welding). The pitch of the spot welding may be suitably selected. Note that in the example shown in FIG. 1, the inner edge of the frame 40 and the inner edge of the magnetic metal member 20 are generally aligned with each other as viewed from the direction normal to the support substrate 60, but a portion of the magnetic metal member 20 may be exposed on the inside of the frame 40. Alternatively, the frame 40 may cover the entire peripheral portion of the magnetic metal member 20 and a portion of the layered member 10.

As described above, in the present embodiment, the step (stretching step) of securing the layered member 10 and the magnetic metal member 20 to the frame 40 while pulling the layered member 10 and the magnetic metal member 20 in a predetermined layer in-plane direction is not performed, and therefore a frame 40 whose rigidity is smaller than those of conventional methods can be used. Therefore, the frame 40 may be formed from a resin such as ABS (acrylonitrile butadiene styrene) or PEEK (polyetheretherketone). The method for attaching together the mask member 30 and the frame 40 is not limited to laser welding. For example, an adhesive may be used to attach together the peripheral portion of the magnetic metal member 20 and the frame 40.

Moreover, in the present embodiment, if the magnetic metal member 20 has a sufficient rigidity, a frame does not need to be provided.

<Other Methods for Manufacturing Vapor Deposition Mask>

With the method described above with reference to FIG. 4 to FIG. 8, the second openings 13 are formed in the layered member 10 after the layered member 10 and the magnetic metal member 20 are attached together, but the second openings 13 may be formed before the layered member 10 and the magnetic metal member 20 are attached together. With the method described above with reference to FIG. 4 to FIG. 8, the support substrate 60 is removed from the mask member 30 before attaching together the mask member 30 and the frame 40, but the support substrate 60 may be removed after attaching together the frame 40 and the mask member 30. Moreover, the second openings 13 may be formed in the layered member 10 after the frame 40 and the mask member 30 are attached together. The frame 40 may be attached to the magnetic metal member 20 before attaching together the layered member 10 and the magnetic metal member 20.

Another method for manufacturing a vapor deposition mask of the present embodiment will now be described with reference to the drawings. In the figures, like reference signs denote like components to those of FIG. 4 to FIG. 8. The description will focus on what is different from the method described above with reference to FIG. 4 to FIG. 8, and the description will be omitted if the formation method, material, thickness, etc., of each layer are the same as those of the method described above.

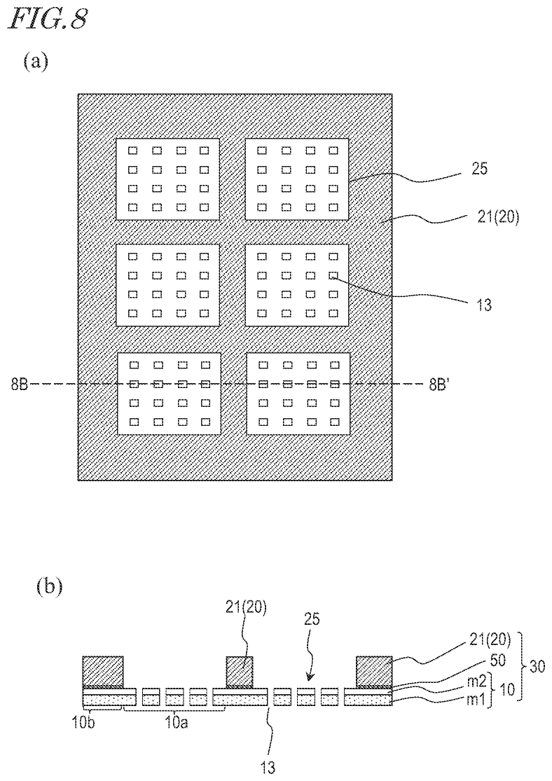

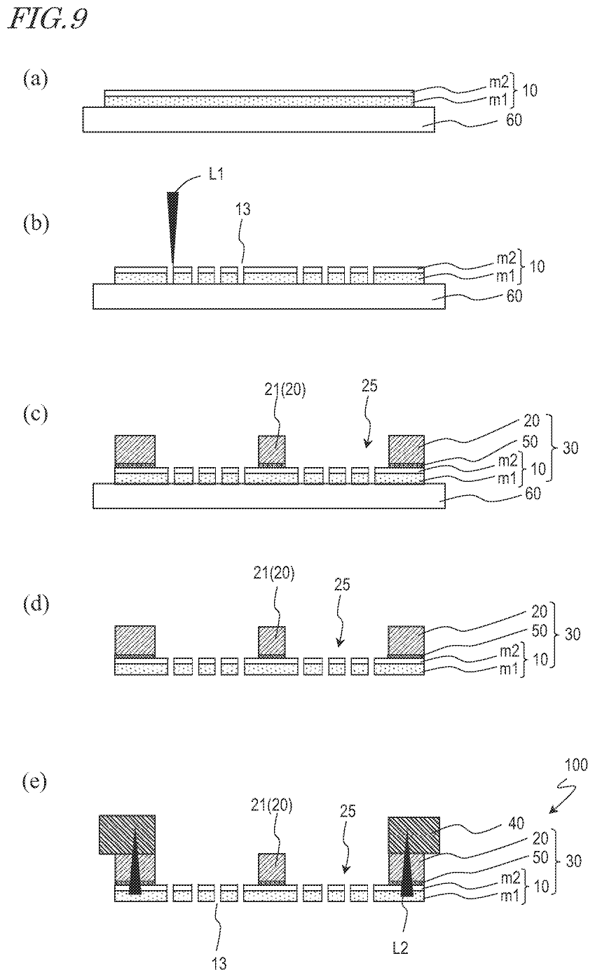

FIGS. 9(a) to 9(e) are process cross-sectional views illustrating another method for manufacturing a vapor deposition mask.

First, as shown in FIG. 9(a), the layered member 10 is formed on the support substrate 60.

Next, as shown in FIG. 9(b), the second openings 13 are formed in the layered member 10 by laser processing. The second openings 13 are formed in regions of the layered member 10 that are located in the first openings 25 of the magnetic metal member 20 when attached to the magnetic metal member 20 in a subsequent step.

Then, as shown in FIG. 9(c), the layered member 10 and the magnetic metal member 20 are attached together with the adhesive layer 50 therebetween. The method of attachment is the same as the method described above with reference to FIG. 5.

Thereafter, as shown in FIG. 9(d), the support substrate 60 is removed from the layered member 10 by a laser lift-off method, for example.

Next, as shown in FIG. 9(e), the frame 40 is provided on the peripheral portion of the magnetic metal member 20 by performing spot welding using the laser beam L2, for example. The vapor deposition mask 100 is obtained as described above.

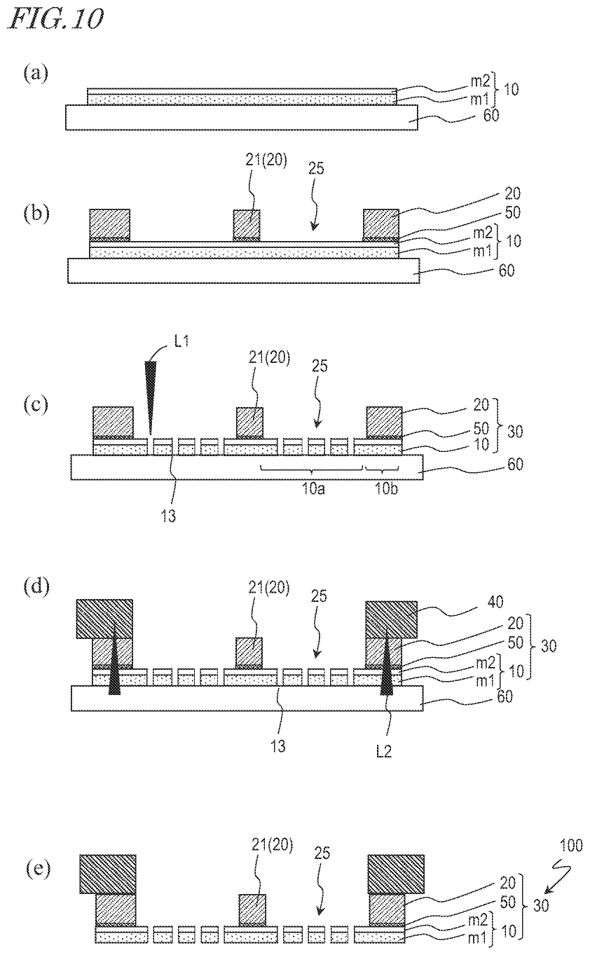

FIGS. 10(a) to 10(e) are process cross-sectional views illustrating another method for manufacturing a vapor deposition mask.

First, as shown in FIG. 10(a), the layered member 10 is formed on the support substrate 60.

Next, as shown in FIG. 10(b), the layered member 10 and the magnetic metal member 20 are attached together with the adhesive layer 50 therebetween.

Then, as shown in FIG. 10(c), the second openings 13 are formed in the layered member 10 by laser processing.

Thereafter, as shown in FIG. 10(d), the frame 40 is provided on the peripheral portion of the magnetic metal member 20 by performing spot welding using the laser beam L2, for example.

Next, as shown in FIG. 10(e), the support substrate 60 is removed from the layered member 10 by a laser lift-off method, for example. The vapor deposition mask 100 is obtained as described above.

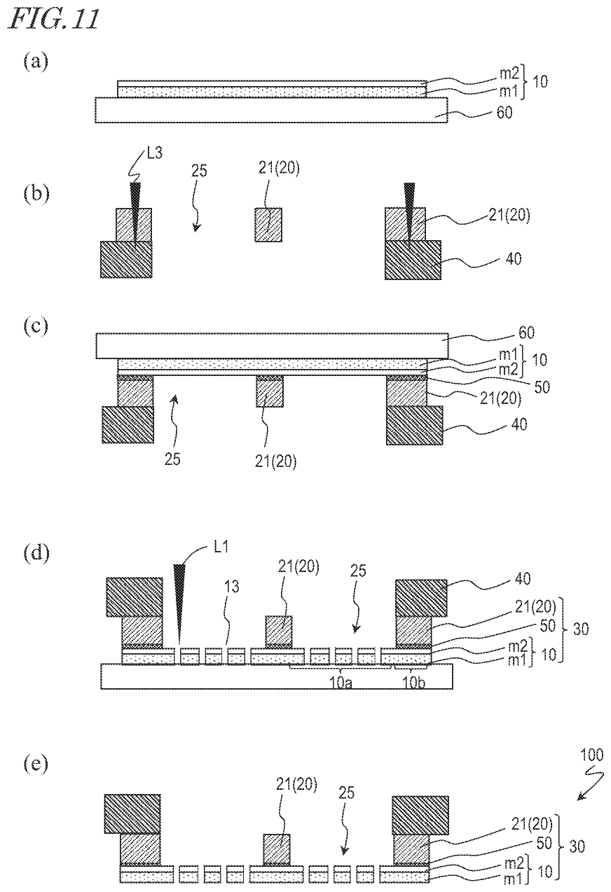

FIGS. 11(a) to 11(e) are process cross-sectional views illustrating still another method for manufacturing a vapor deposition mask.

First, as shown in FIG. 11(a), the layered member 10 is formed on the support substrate 60.

As shown in FIG. 11(b), the magnetic metal member 20 is attached to the frame 40, thereby forming a frame structure. Specifically, the frame 40 is mounted on the peripheral portion of the magnetic metal member 20, and the peripheral portion and the frame 40 are attached together. Herein, the peripheral portion of the magnetic metal member 20 and the frame 40 are welded together by irradiating the laser beam L3 from the magnetic metal member 20 side. For example, spot welding may be performed at a plurality of spots with predetermined intervals therebetween. Note that the magnetic metal member 20 may be attached to the frame 40 while a certain amount of tension is applied to the magnetic metal member 20 in a predetermined direction by using a stretch welder. Note however that in the present embodiment, there is no limitation as long as the magnetic metal member 20 is secured to the frame 40, and there is no need to apply a large tension.

Then, as shown in FIG. 11(c), the layered member 10 and the magnetic metal member 20 are attached together with the adhesive layer 50 therebetween.

Next, as shown in FIG. 11(d), the second openings 13 are formed in the layered member 10 by laser processing.

Thereafter, as shown in FIG. 11(e), the support substrate 60 is removed from the layered member 10 by a laser lift-off method, for example. The vapor deposition mask 100 is obtained as described above.

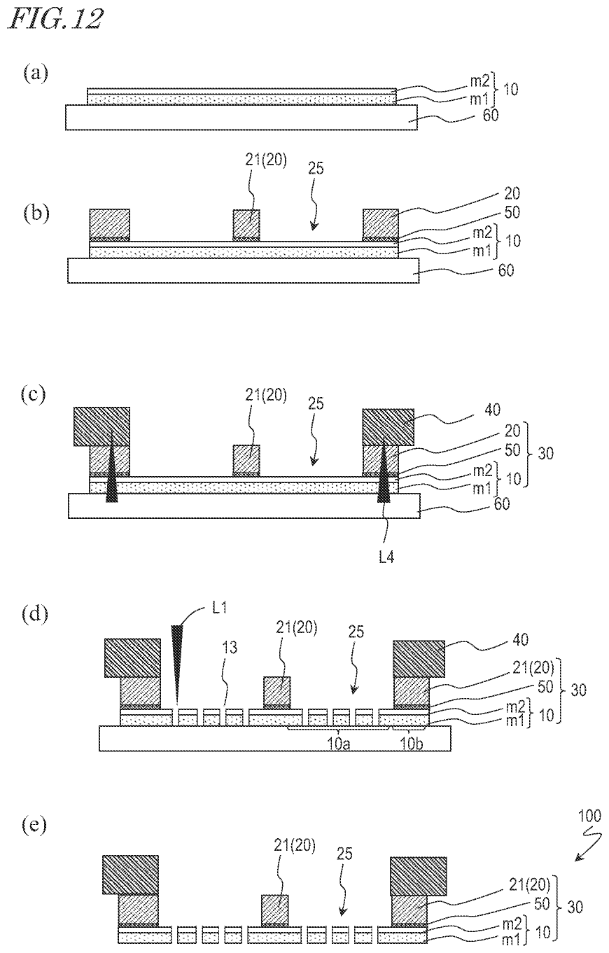

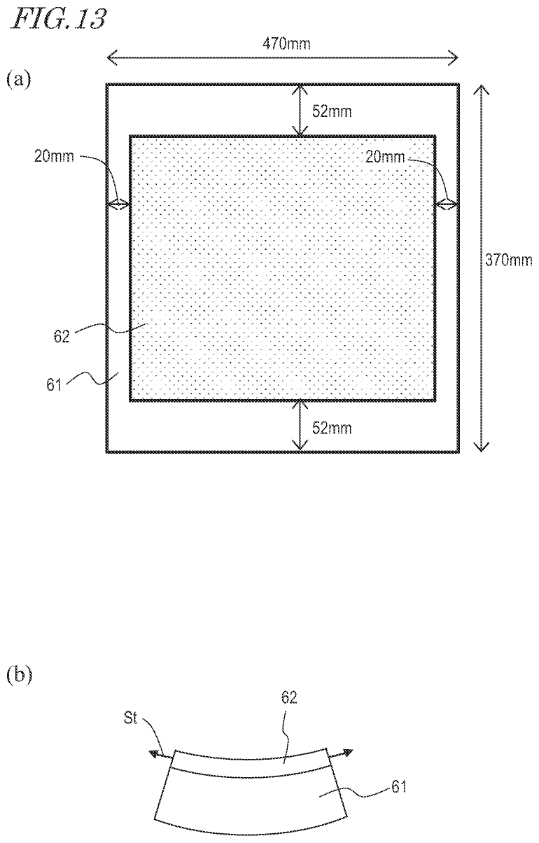

FIGS. 12(a) to 12(e) are process cross-sectional views illustrating still another method for manufacturing a vapor deposition mask.

First, as shown in FIG. 12(a), the layered member 10 is formed on the support substrate 60.

Next, as shown in FIG. 12(b), the layered member 10 and the magnetic metal member 20 are attached together with the adhesive layer 50 therebetween.

Then, as shown in FIG. 12(c), the frame 40 is provided on the peripheral portion of the magnetic metal member 20 by performing spot welding using the laser beam L4, for example.

Thereafter, as shown in FIG. 12(d), the second openings 13 are formed in the layered member 10 by laser processing.

Next, as shown in FIG. 12(e), the support substrate 60 is removed from the layered member 10 by a laser lift-off method, for example. The vapor deposition mask 100 is obtained as described above.

As described above, the vapor deposition mask 100 of the present embodiment can be manufactured by various methods. Note that with the method illustrated in FIG. 9, there is a need for a high-precision positioning when attaching together the layered member 10 with the second openings 13 formed therein and the magnetic metal member 20. In contrast, forming the second openings 13 after attaching together the layered member 10 and the magnetic metal member 20 is advantageous because it eliminates the need for performing such a high-precision positioning.

With the methods illustrated in FIG. 10 to FIG. 12, the frame 40 is attached before removing the support substrate 60. In this case, the support substrate 60 with the heavy and bulky frame 40 attached thereto is installed on the stage of a laser lift-off device, and the support substrate 60 is removed. Therefore, the stage of the laser lift-off device to be used needs to be larger and stronger than with other methods. The distance WD (work distance) between the laser head and the stage needs to be increased. In contrast, performing the step of attaching the frame 40 after removing the support substrate 60 is more practical because it imposes no such limitation as described above on the size, strength, WD, etc., of the stage of the laser lift-off device.

With the manufacturing methods illustrated in FIG. 9 to FIG. 12, since a plurality of second openings 13 are formed in the layered member 10 formed on the support substrate 60, second openings 13 of an intended size can be formed with a higher precision than with conventional methods, and it is possible to suppress the occurrence of a burr 98 (see FIG. 20).

Note that while the support substrate 60 is removed from the layered member 10 after forming the second openings 13 in the layered member 10 with the methods described above, the second opening 13 may be formed in the layered member 10 after removing the support substrate 60 from the layered member 10. In such a case, as with conventional methods, the laser processing of the layered member 10 may be performed with the first layer m1 side of the layered member 10 adhering to the glass substrate with a liquid such as ethanol therebetween. The liquid is preferably a liquid with a high boiling point in order to prevent the occurrence of bubbles and evaporation. The layered member 10 has a protruding surface shape and bubbles are therefore less likely to be introduced between the layered member 10 and the glass substrate, thus better preventing the occurrence of burrs than with conventional methods. Even if a burr occurs on the layered member 10, at the time of vapor deposition, the layered member 10 is warped so as to protrude toward the vapor deposition substrate side and the portion where the burr is formed is also pressed against the vapor deposition substrate. Therefore, it is possible to reduce the influence of the burr. Note however that in order to effectively suppress the occurrence of burrs, it is preferred that the second openings 13 are formed in the layered member 10 before removing the support substrate 60.

In the present embodiment, the layered member 10 is formed on the support substrate 60, and the layered member 10, which is supported on the support substrate 60, and the magnetic metal member 20 are attached together. Since the layered member 10 has a predetermined tensile stress as a residual stress, the stretching step of stretching and attaching the layered member 10 to the frame is not performed. There is no need for the stretching step using a large-scale stretcher, and it is advantageous in that it is possible to reduce the manufacturing cost. Since the stretching step is not performed, it is possible to reduce the rigidity of the frame 40 as compared with those of conventional methods as described above, and it is possible to increase the degree of freedom in the selection of materials of the frame 40 and the degree of freedom in design such as the frame width and the thickness.

With the conventional method described in Patent Document No. 1, etc., the laser processing on a resin film is performed after the resin film is secured to the frame in the stretching step. In contrast, in the present embodiment, the step of attaching the frame 40 may be performed before the laser processing of the layered member 10 or may be performed after the laser processing. Performing the step of attaching the frame 40 after the laser processing has an advantage as follows. The mask member 30 supported on the support substrate 60 before the frame 40 is attached thereto (including the mask member before the laser processing) is lighter in weight and easier to handle as compared with the mask member 30 after the frame 40 is attached thereto, thereby making it easier to install on a laser processing machine and to perform an operation such as conveying. Since the frame 40 is not attached, it is easier to irradiate the laser beam L1 onto the layered member 10 and to process the layered member 10. Moreover, while there is a need to remove the layered mask from the frame if the laser processing of the resin layer is unsuccessful with the method of Patent Document No. 1, there is no need to perform such a removing step if the laser processing is performed before the frame 40 is attached.

(Relationship Between Heat Treatment Condition and Tensile Stress of Resin Layer)

The present inventors studied the relationship between the formation conditions (heat treatment conditions) of the resin layer and the tensile stress of the resin layer, using a polyimide layer as an example. The method and results are described below.

Method for Producing Samples A to C

Samples A to C were obtained by forming a polyimide film 62 using a thermosetting polyimide on a glass substrate 61 while varying the heat treatment conditions. FIG. 13(a) is a top view of Samples A to C.

First, a glass substrate (AN-100 from Asahi Glass) 61 was provided as a support substrate. The glass substrate 61 had a thermal expansion coefficient of 3.8 ppm/° C., a size of 370 mm×470 mm and a thickness of 0.5 mm.

Then, as shown in FIG. 13(a), a polyimide varnish (U-Varnish-S from Ube Industries, Ltd.) was applied on a predetermined region (330 mm×366 mm) of the glass substrate 61. The glass transition temperature Tg of the polyimide is 330° C., and the thermal expansion coefficient thereof is about the same as the thermal expansion coefficient of the glass substrate.

Next, the glass substrate 61 with the polyimide varnish applied thereon was subjected to a heat treatment under a vacuum atmosphere at a pressure: 20 Pa, thereby forming the polyimide film 62. In the heat treatment, the temperature was raised from room temperature (herein, 25° C.) to 500° C. (maximum temperature) and held at 500° C. for a predetermined amount of time. Thereafter, a nitrogen gas was supplied as a purge gas, followed by rapid cooling (3 min). Table 1 shows, for each sample, the temperature increase time to 500° C., the holding time at 500° C., the temperature increase rate (from room temperature to when reaching 500° C.) and the thickness of the polyimide film 62.

Thus, glass substrates 61 with the polyimide film 62 formed thereon were obtained as Samples A to C. In Samples A to C, the tensile stress of the polyimide film 62 gave a compressive stress to the glass substrate 61, thereby warping the glass substrate 61 so as to form a concave surface as schematically shown in FIG. 13(b). Table 1 shows the average value of the amount of warp of the glass substrate 61 in the long-side direction and the short-side direction.

Calculation of Tensile Stress of Polyimide Film 62

Next, for Samples A to C, the tensile stress of the polyimide film 62 was calculated from the amount of warp of the glass substrate 61. The results are shown in Table 1. The tensile stress can be obtained, using Stoney's equation, from the thickness, the Young's modulus, the Poisson's ratio of the glass substrate 61, the thickness of the polyimide film 62, and the radius of curvature (approximate value) of the warp of the glass substrate 61.

Table 1 also shows the results of a case where the polyimide film was produced under conditions where the temperature increase rate is small (referred to as “Sample D”). As shown in Table 1, for Sample D, the temperature was raised to 450° C. in a stepwise manner by holding the temperature for a predetermined amount of time upon reaching 120° C., 150° C. and 180° C. The tensile stress for Sample D is a value calculated while assuming that the warp of the glass substrate 61 is 10 μm.

TABLE 1

| | | Sample A | Sample B | Sample C | Sample D |
|---|---|---|---|---|---|
| Heat treatment | Temperature | Room temperature to 500° C. | | | Room temperature to |
| conditions | | | | | 450° C. |
| | Pressure | 20 Pa | | | Atmospheric pressure |
| | Heating time | 8 min | 13 min | 21 min | 195 min |
| | | Temperature | Temperature | Temperature | Hold at 120° C. for 10 min |
| | | increase: | increase: | increase: | Hold at 150° C. for 10 min |
| | | 3 min | 8 min | 16 min | Hold at 180° C. for 60 min |
| | | Hold: 5 min | Hold: 5 min | Hold: 5 min | Hold at 450° C. for 30 min |
| | Temperature | 158° C./min | 59° C./min | 30° C./min | 5° C./min |
| | increase rate | | | | |

| | | | | |
|---|---|---|---|---|
| Thickness of polyimide | 10 | 20 | 20 | 20 |
| film (μm) | | | | |
| Amount of warp in long- | 23 | 620 | 230 | 10 or less |
| side direction of glass | | | | |
| substrate (μm) | | | | |
| Amount of warp in short- | 6 | 400 | 130 | 10 or less |
| side direction of glass | | | | |
| substrate (μm) | | | | |
| Tensile stress of polyimide | 0.2 | 9.6 | 3.3 | 0.2 |
| film (MPa) | | | | |

Moreover, six samples B1 to B6 were produced under the same heat treatment conditions, and the tensile stress occurring in the polyimide film 62 was calculated. The heat treatment conditions for Samples B1 to B6 was the same as Sample B (room temperature to 500° C., pressure: 20 Pa, heating time: 13 min (temperature increase 8 min+hold 5 min), and temperature increase rate: 59° C./min). Note however that the rate of depressurizing the chamber where the glass substrate 61 with a polyimide varnish applied thereon is installed, before the heat treatment, was set to be lower than Sample B. Also for these samples, the tensile stress of the polyimide film was obtained from the amount of warp of the glass substrate as described above. The results are shown in Table 2.

TABLE 2

| | B1 | B2 | B3 | B4 | B5 | B6 |
|---|---|---|---|---|---|---|
| Thickness of polyimide film | 20 | | | | | |
| (μm) | | | | | | |
| Amount of warp in long- | 750 | 700 | 710 | 680 | 690 | 670 |
| side direction of glass sub- | | | | | | |
| strate (μm) | | | | | | |
| Amount of warp in short- | 500 | 500 | 520 | 470 | 500 | 540 |
| side direction of glass sub- | | | | | | |
| strate (μm) | | | | | | |
| Tensile stress of polyimide | 11.7 | 11.4 | 11.7 | 10.8 | 11.2 | 11.4 |
| film (mPa) | | | | | | |

From the results above, it was confirmed that the tensile stress occurring in the resin layer on the support substrate can be controlled by heat treatment conditions. For example, it was found that it is possible to form a resin layer having a higher tensile stress by increasing the temperature increase rate. Note that while the heat treatment was performed herein while varying the temperature increase rate for different samples, the magnitude of the tensile stress of the resin layer can also be varied by changing a heat treatment condition other than the temperature increase rate.

### EXAMPLES

Then, vapor deposition masks of examples will be described. Table 3 shows structures of layered members 10 of vapor deposition masks of Examples 1 to 3. Note that in Examples 1 to 3, a glass substrate (AN-100 from Asahi Glass, thermal expansion coefficient: 3.8 ppm/° C.) was used as the support substrate for forming the layered member 10.

TABLE 3

| | | | | Internal | Elastic |
|---|---|---|---|---|---|
| | | | Thickness | stress σ | modulus |
| | | Material | a (μm) | (GPa) | E (GPa) |
| Example 1 | First layer | Polyimide | 15 | 5 × 10⁻³ | 9 |
| | Second | Titanium | 0.1 | 1.2 | 300 |
| | layer | oxide | | | |
| Example 2 | First layer | Polyimide | 15 | 5 × 10⁻³ | 9 |
| | Second | Acrylic | 1 | 2 × 10⁻³ | 3 |
| | layer | resin | | | |
| Example 3 | First layer | Polyimide | 20 | 3 × 10⁻³ | 9 |
| | Second | Polyimide | 20 | 10 × 10⁻³ | 9 |
| | layer | | | | |

As will be described below, in each example, at the first temperature T1 (herein, 25° C.), the elastic moduli E1 and E2 of the first layer m1 and the second layer m2, the thicknesses a1 and a2 of the first layer m1 and the second layer m2 and the internal stresses σ1 and σ2 of the first layer m1 and the second layer m2 (σ1 and σ2 are positive for tensile stress) satisfy Expressions (1) and (2) below. The Young's modulus of each layer is assumed to be approximately constant in the range from the temperature T0 to the first temperature T1.

σ1/E1−σ2/E2<0 (1)

0<a1×σ1+a2×σ2 (2)

### Example 1

In Example 1, first, a polyimide layer whose thickness a1 is 15 μm is formed as the first layer m1 on a glass substrate by using the same thermosetting polyimide as Samples A to C described above. The polyimide layer formation temperature T1 is 500° C., and the temperature increase condition is 59° C./min, for example.

Next, the amount of warp x1 of the glass substrate with a polyimide layer formed thereon is measured at the first temperature T1 (herein, room temperature), and the internal stress σ1 of the polyimide layer is calculated using Stoney's equation.

Then, a titanium oxide (TiO₂) layer whose thickness a2 is 0.1 μm is formed by a sputtering method on the first layer m1 as the second layer m2. The titanium oxide layer formation temperature t2 is 50° C. The temperature t2 corresponds to the temperature T0 at the time of formation of the layered member.

Next, the amount of warp x2 of the glass substrate after the formation of the titanium oxide layer is measured at the first temperature T1 (herein, room temperature). From the difference between the amount of warp x2 and the amount of warp x1 before the formation of the titanium oxide layer, the internal stress σ2 of the titanium oxide layer is calculated using Stoney's equation.

In Example 1, Table 3 shows values of the internal stresses σ1 and σ2 obtained from the amount of warp x1, x, 2. Since σ1>0 and σ2>0, the internal stresses σ1 and σ2 are tensile stresses. Therefore, a1×σ1+a2×σ2>0, thus satisfying Expression (2).

As shown below, σ1/E1−σ2/E2<0, thus satisfying Expression (1), and it is confirmed that the warp is such as to protrude toward the first layer m1 side (5<0).

σ1/E1=0.00056

σ2/E2=0.00400

σ1/E1−σ2/E2=−0.00344<0

Note that assuming L(m)=0.1, replacing (α2−α1) (T1−T0) in the theoretical bimetal expression (3) with (σ1/E1−σ2/E2) to obtain the curvature ρ, and then calculating the amount of warp δ from the theoretical expression (4), gives the following.

ρ(m)=−0.00338

δ(m)=−0.370

Also from the fact that these values p and 5 are negative, it is confirmed that the layered member 10 warps so as to protrude toward the first layer m1 side (δ<0).

### Example 2

In Example 2, first, a polyimide layer whose thickness a1 is 15 μm is formed as the first layer m1 on a glass substrate by using the same material as Example 1. The polyimide layer formation temperature T1 and the temperature increase condition are the same as those for the polyimide layer of Example 1. Next, as in Example 1, the amount of warp x1 is measured, and the internal stress σ1 is calculated using Stoney's equation.

Then, as the second layer m2, an acrylic resin layer whose thickness a2 is 1 μm is formed by using a UV-curable acrylic resin material on the first layer m1. The acrylic resin layer formation temperature t2 (=the temperature T0 at the time of formation of the layered member) is room temperature.

Next, at the first temperature T1, the amount of warp x2 is measured after the formation of the titanium oxide layer. The internal stress σ2 of the titanium oxide layer is calculated using Stoney's equation from the difference between the amount of warp x2 and the amount of warp x1 before the formation of the titanium oxide layer.

In Example 2, Table 3 shows values of the internal stresses σ1 and σ2 obtained from the amount of warp x1, x, 2. Since a1>0 and a2>0, the internal stresses σ1 and σ2 are tensile stresses. Therefore, a1−σ1+a2×σ2>0, thus satisfying Expression (2).

As in Example 1, the value of σ1/E1−σ2/E2 is obtained as follows for the layered member 10 of Example 2.

σ1/E1−σ2/E2=0.000556−0.000667<0

It can be seen that the layered member 10 of Example 2 also satisfies Expression (1) and warps so as to protrude toward the first layer m1 side (δ<0).

### Example 3

In Example 3, the same polyimide layer as Sample C is formed as the first layer m1, and the same polyimide layer as Sample B is formed as the second layer m2. Also with the layered member 10 of Example 3, σ1 and σ2 are both tensile stress and satisfy Expression (2). Moreover, σ1/E1−σ2/E2<0, satisfying Expression (1), and it warps so as to protrude toward the first layer m1 side (δ<0).

<Another Structure Example of Vapor Deposition Mask>

FIG. 15 is a cross-sectional view showing a variation of a vapor deposition mask of the present embodiment. As illustrated in FIG. 15, the adhesive layer 50 may be arranged only on the peripheral edge portion of the layered member 10. Where a portion of the magnetic metal member 20 that overlaps with the frame to be provided later is referred to as the “peripheral portion” and a portion thereof that is located in the opening of the frame as the “mask portion”, the adhesive layer 50 may be arranged only between the peripheral portion of the magnetic metal member 20 and the layered member 10. In the mask portion, the solid portion 21 of the magnetic metal member 20 and the layered member 10 are not bonded together. In this case, the layered member 10 may be in a protruding surface shape across the entire mask portion.

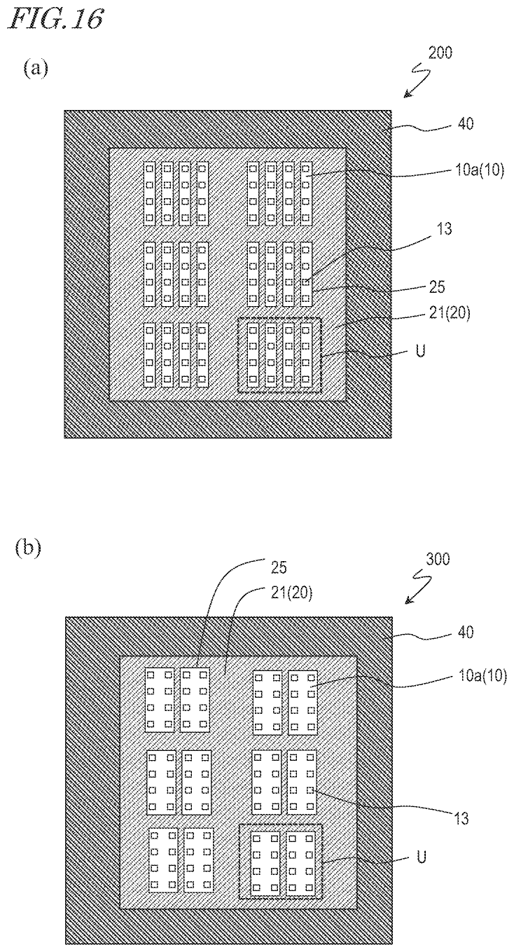

FIGS. 16(a) and 16(b) are plan views schematically showing other vapor deposition masks 200 and 300 of the present embodiment. In these figures, like components to those of FIG. 1 are denoted by like reference signs. In the following description, only differences from the vapor deposition mask 100 will be described.

With the vapor deposition masks 200 and 300, the magnetic metal member 20 includes a plurality of first openings 25 in the unit region U. Two or more second openings 13 are located in each first opening 25 (needless to say, the present invention is not limited to the number of second openings shown in the figure).

As shown in FIG. 16(a), the first openings 25 may be slits arranged in the unit region U, wherein a slit is arranged for each column (or row) of second openings 13, which are arranged in an array extending in the row direction and the column direction. Alternatively, as shown in FIG. 16(b), one first opening 25 may be arranged for each sub-area that includes a plurality of columns and a plurality of rows of second openings 13.

Note that while FIG. 1 and FIG. 16 illustrate vapor deposition masks having a plurality of unit regions U, the number of unit regions U and the arrangement method therefor, the number of second openings 13 and the arrangement method therefor in each unit region U are not limited to the examples shown in the figures but are determined based on the configuration of the device to be manufactured. The number of unit regions U may be singular.

(Method for Manufacturing Organic Semiconductor Device)

A vapor deposition mask according to an embodiment of the present invention can suitably be used in the vapor deposition step in a method for manufacturing an organic semiconductor device.

The following description is directed to, as an example, a method for manufacturing an organic EL display device.

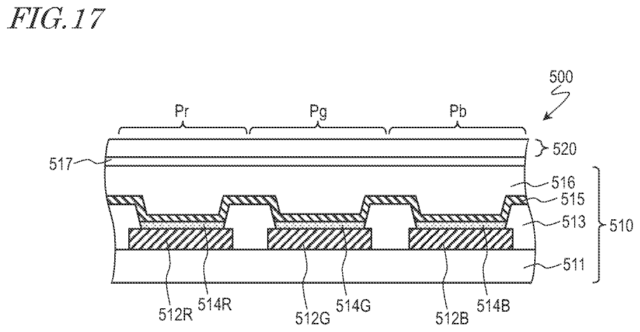

FIG. 17 is a cross-sectional view schematically showing an organic EL display device 500 of a top emission type.

As can be seen from FIG. 17, the organic EL display device 500 includes an active matrix substrate (TFT substrate) 510 and an encapsulation substrate 520, and includes a red pixel Pr, a green pixel Pg and a blue pixel Ph.

The TFT substrate 510 includes an insulative substrate, and a TFT circuit formed on the insulative substrate (neither is shown in the figure). A flattening layer 511 is provided so as to cover the TFT circuit. The flattening layer 511 is formed from an organic insulative material.

Lower electrodes 512R, 512G and 512B are provided on the flattening layer 511. The lower electrodes 512R, 512G and 512B are formed in the red pixel Pr, the green pixel Pg and the blue pixel Pb, respectively. The lower electrodes 512R, 512G and 512B are each connected to the TFT circuit, and function as an anode. A bank 513 covering the edge portion of the lower electrodes 512R, 512G and 512B is provided between adjacent pixels. The bank 513 is formed from an insulative material.

Organic EL layers 514R, 514G and 514B are provided on the lower electrodes 512R, 512G and 512B of the red pixel Pr, the green pixel Pg and the blue pixel Pb, respectively. The organic EL layers 514R, 514G and 514B each have a layered structure including a plurality of layers formed from an organic semiconductor material. For example, the layered structure includes a hole injection layer, a hole transport layer, a light emitting layer, an electron transport layer and an electron injection layer that are arranged in this order from the side of the lower electrodes 512R, 512G and 512B. The organic EL layer 514R of the red pixel Pr includes a light emitting layer that emits red light. The organic EL layer 514G of the green pixel Pg includes a light emitting layer that emits green light. The organic EL layer 514B of the blue pixel Pb includes a light emitting layer that emits blue light.

An upper electrode 515 is provided on the organic EL layers 514R, 514G and 514B. The upper electrode 515 is formed, by using a transparent conductive material, so as to be continuous over the entire display area (i.e., as a shared member among the red pixel Pr, the green pixel Pg and the blue pixel Pb), and functions as a cathode. A protection layer 516 is provided on the upper electrode 515. The protection layer 516 is formed from an organic insulative material.

The structure of the TFT substrate 510 described above is encapsulated by the encapsulation substrate 520, which is bonded to the TFT substrate 510 via a transparent resin layer 517.

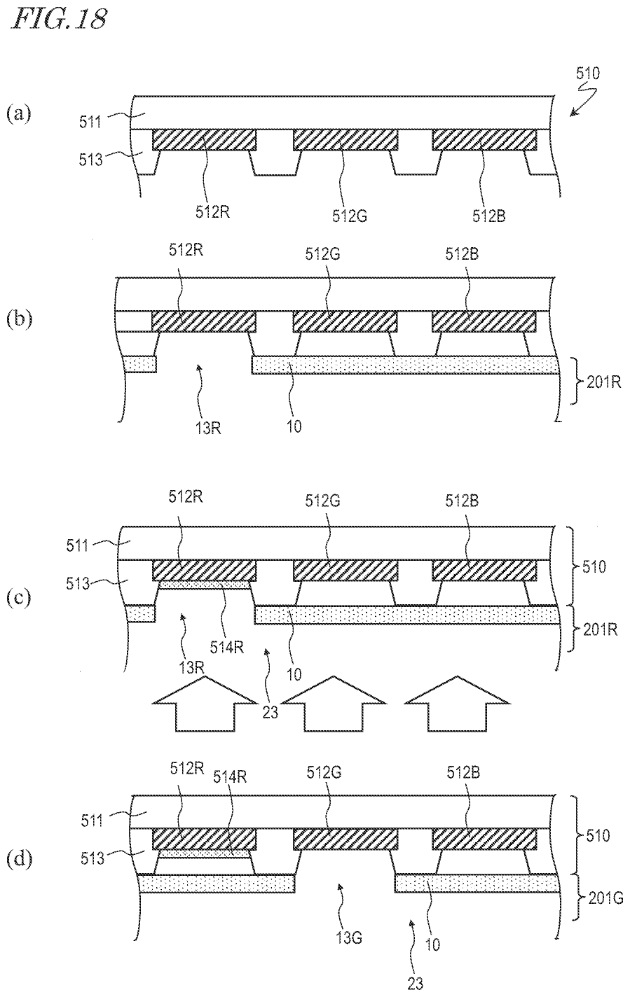

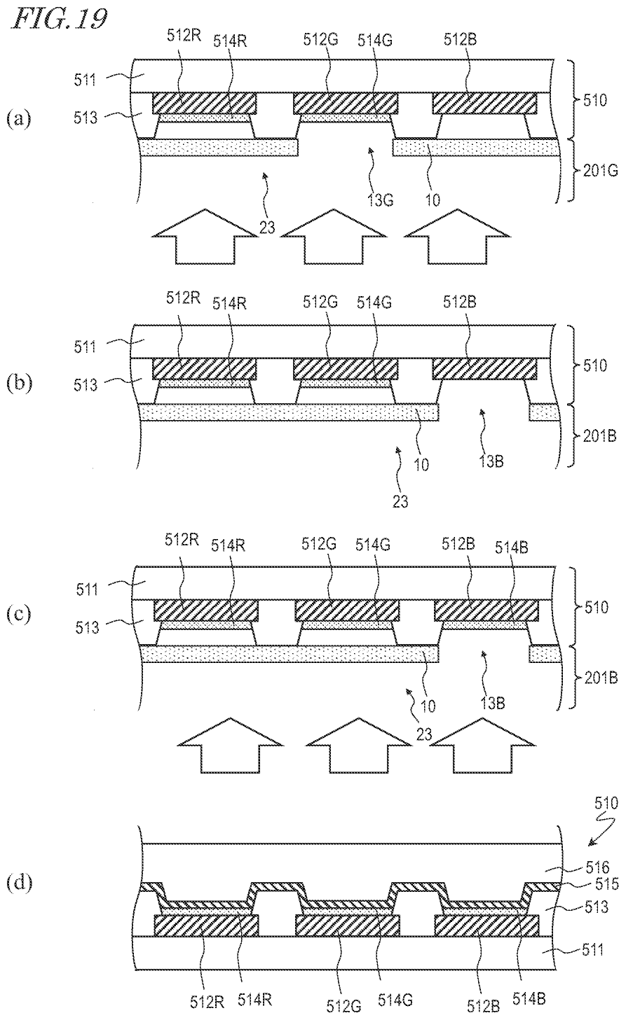

The organic EL display device 500 can be produced as follows by using a vapor deposition mask according to an embodiment of the present invention. FIGS. 18(a) to 18(d) and FIGS. 19(a) to 19(d) are process cross-sectional views showing a manufacturing process of the organic EL display device 500. Note that the following description will focus on the step of vapor-depositing an organic semiconductor material on the work (forming the organic EL layers 514R, 514G and 514B on the TFT substrate 510) by using a vapor deposition mask 101R for red pixels, a vapor deposition mask 101G for green pixels and a vapor deposition mask 101B for blue pixels in turns.

First, as shown in FIG. 18(a), the TFT substrate 510 is provided, wherein the TFT substrate 510 includes the TFT circuit, the flattening layer 511, the lower electrodes 512R, 512G and 512B and the bank 513 formed on an insulative substrate. The steps of forming the TFT circuit, the flattening layer 511, the lower electrodes 512R, 512G and 512B and the bank 513 can be carried out by any of various methods known in the art.

Next, as shown in FIG. 18(b), a carrier device is used to arrange the TFT substrate 510 close to the vapor deposition mask 101R, which is held in the vapor deposition device. In this process, the vapor deposition mask 101R and the TFT substrate 510 are positioned so that the second opening 13R of the layered member 10 overlaps the lower electrode 512R of the red pixel Pr. A magnetic chuck (not shown) arranged on the opposite side from the vapor deposition mask 101R with respect to the TFT substrate 510 is used to hold the vapor deposition mask 101R in close contact with the TFT substrate 510.

Then, as shown in FIG. 18(c), organic semiconductor materials are successively deposited on the lower electrode 512R of the red pixel Pr by vapor deposition, thereby forming the organic EL layer 514R including a light emitting layer that emits red light.

Next, as shown in FIG. 18(d), the vapor deposition mask 101G is placed in the vapor deposition device, replacing the vapor deposition mask 101R. The vapor deposition mask 101G and the TFT substrate 510 are positioned together so that the second opening 13G of layered member 10 overlaps the lower electrode 512G of the green pixel Pg. A magnetic chuck is used to hold the vapor deposition mask 101G in close contact with the TFT substrate 510.

Then, as shown in FIG. 19(a), organic semiconductor materials are successively deposited on the lower electrode 512G of the green pixel Pg by vapor deposition, thereby forming the organic EL layer 514G including a light emitting layer that emits green light.

Next, as shown in FIG. 19(b), the vapor deposition mask 101B is placed in the vapor deposition device, replacing the vapor deposition mask 101G. The vapor deposition mask 101B and the TFT substrate 510 are positioned together so that the second opening 13B of layered member 10 overlaps the lower electrode 512B of the blue pixel Pb. A magnetic chuck is used to hold the vapor deposition mask 101B in close contact with the TFT substrate 510.

Then, as shown in FIG. 19(c), organic semiconductor materials are successively deposited on the lower electrode 512B of the blue pixel Pb by vapor deposition, thereby forming the organic EL layer 514B including a light emitting layer that emits blue light.

Next, as shown in FIG. 19(d), the upper electrode 515 and the protection layer 516 are formed successively on the organic EL layers 514R, 514G and 514B. The formation of the upper electrode 515 and the protection layer 516 can be carried out by any of various methods known in the art. Thus, the TFT substrate 510 is obtained.

Then, the encapsulation substrate 520 is bonded to the TFT substrate 510 via the transparent resin layer 517, thereby completing the organic EL display device 500 shown in FIG. 17.

Note that with the organic EL display device 500, an encapsulation film may be used instead of the encapsulation substrate 520. Alternatively, instead of using an encapsulation substrate (or an encapsulation film), a thin film encapsulation (TFE) structure may be provided over the TFT substrate 510. A thin film encapsulation structure includes a plurality of inorganic insulating films such as silicon nitride films, for example. The thin film encapsulation structure may further include an organic insulative film.

Herein, three vapor deposition masks 101R, 101G and 101B corresponding respectively to the organic EL layers 514R, 514G and 514B of the red pixel Pr, the green pixel Pg and the blue pixel Pb are used. However, the organic EL layers 514R, 514G and 514B corresponding to the red pixel Pr, the green pixel Pg and the blue pixel Pb may be formed by successively shifting one vapor deposition mask.

Alternatively, in order to prevent contamination, the organic EL layers 514R, 514G and 514B having a layered structure may each be formed by using a different vapor deposition mask.

Only one or more of the organic EL layers 514R, 514G and 514B, including the light emitting layers, may be formed by using the vapor deposition mask of the present embodiment. For example, layers other than the light emitting layer (the hole injection layer, the hole transport layer, the electron transport layer, the electron injection layer, etc.) may be formed by using an open mask with openings therein corresponding to unit regions, and the light emitting layers of the red pixel, the green pixel and the blue pixel may be formed by using the vapor deposition mask of the present embodiment. Where a microcavity structure is applied, only the light emitting layer and the hole transport layer may be formed by using a vapor deposition mask, and the other layers may be formed by using an open mask.

Note that although the organic EL display device 500 of a top emission type is illustrated in the above description, it is needless to say that the vapor deposition mask of the present embodiment may be used for manufacturing an organic EL display device of a bottom emission type.

An organic EL display device to be manufactured by using the vapor deposition mask of the present embodiment does not necessarily need to be a rigid device. The vapor deposition mask of the present embodiment can suitably be used in the manufacture of a flexible organic EL display device. In a method for manufacturing a flexible organic EL display device, a TFT circuit, etc., are formed on a polymer layer (e.g., a polyimide layer) formed on a support substrate (e.g., a glass substrate), and the polymer layer, together with the layered structure thereon, is removed the support substrate (e.g., a laser lift off method is used) after the formation of a protection layer.

The vapor deposition mask of the present embodiment may be also used in the manufacture of an organic semiconductor device other than an organic EL display device, and can particularly suitably be used in the manufacture of an organic semiconductor device for which it is necessary to form a vapor deposition pattern having a high definition.

### INDUSTRIAL APPLICABILITY

The vapor deposition mask according to an embodiment of the present invention can suitably be used in the manufacture of an organic semiconductor device such as an organic EL display device, and can particularly suitably be used in the manufacture of an organic semiconductor device for which it is necessary to form a vapor deposition pattern having a high definition.

### REFERENCE SIGNS LIST

10 Layered member
10a First region
10b Second region
11 Warp
13 Second opening
20 Magnetic metal member
21 Solid pattern portion
25 First opening
30 Mask member
40 Frame
50 Adhesive layer
60 Support substrate
70 Vapor deposition substrate
m1 First layer
m2 Second layer
L1, L1, L3, L4 Laser beam
100, 200, 300 Vapor deposition mask
500 Organic EL display device
510 TFT substrate
511 Flattening layer
512B, 512G, 512R Lower electrode
513 Bank
514B, 514G, 514R Organic EL layer
515 Upper electrode
516 Protection layer
517 Transparent resin layer
520 Encapsulation substrate
Pb Blue pixel
Pg Green pixel
Pr Red pixel
U Unit region

1. A vapor deposition mask comprising:
a magnetic metal member including at least one first opening; and
a layered member that is arranged on the magnetic metal member so as to cover the at least one first opening and has a plurality of second openings located in the at least one first opening, wherein:
the layered member includes a first layer and a second layer that is arranged between the first layer and the magnetic metal member; and
in the at least one first opening, at a first temperature that is greater than or equal to room temperature, an elastic modulus E1 of the first layer, a thickness a1 of the first layer, an internal stress σ1 of the first layer, an elastic modulus E2 of the second layer, a thickness a2 of the second layer and an internal stress σ2 of the second layer (where σ1 and σ2 are positive for tensile stress) satisfy Expressions (1) and (2) below:
σ1/E1−σ2/E2<0 (1)
0<a1×σ1+a2×σ2 (2).

2. The vapor deposition mask according to claim 1, wherein the first temperature is greater than or equal to room temperature and less than or equal to 60° C.

3. The vapor deposition mask according to claim 1, wherein at the first temperature, a portion of the layered member that is located in the at least one first opening is warped so as to protrude toward a side opposite to the magnetic metal member.

4. The vapor deposition mask according to claim 1, further comprising an adhesive layer that is located between the layered member and the magnetic metal member and attaches together the layered member and the magnetic metal member.

5. The vapor deposition mask according to claim 1, wherein the first layer and the second layer are each a resin layer or formed from an inorganic material other than a metal material.

6. The vapor deposition mask according to claim 1, wherein either one of the first layer and the second layer is a metal layer.

7. The vapor deposition mask according to claim 1, wherein at least one of the first layer and the second layer is a resin layer.

8. The vapor deposition mask according to claim 5, wherein the first layer and the second layer are both resin layers.

9. (canceled)

10. (canceled)

11. The vapor deposition mask according to claim 5, wherein the first layer is formed by using a polyimide layer and the second layer is formed by using an inorganic material other than a metal material.

12. The vapor deposition mask according to claim 1, wherein only the layered member is arranged so as to cover the at least one first opening of the magnetic metal member, and the layered member is made only of the first layer and the second layer.

13. The vapor deposition mask according to claim 1, further comprising a frame that supports the magnetic metal member.

14. The vapor deposition mask according to claim 1, wherein the magnetic metal member has an open mask structure.

15. A method for manufacturing a vapor deposition mask comprising the steps of:
(A) providing a magnetic metal member having at least one first opening;
(B) providing a substrate;
(C) forming a layered member on a surface of the substrate, the layered member including a first layer and a second layer formed on the first layer;
(D) securing the layered member formed on the surface of the substrate on the magnetic metal member so as to cover the at least one first opening;
(E) forming a plurality of second openings in the layered member; and
(F) removing the layered member from the substrate,
wherein in the at least one first opening, at a first temperature that is greater than or equal to room temperature, an elastic modulus E1 of the first layer, a thickness a1 of the first layer, an internal stress σ1 of the first layer, an elastic modulus E2 of the second layer, a thickness a2 of the second layer and an internal stress σ2 of the second layer (where σ1 and σ2 are positive for tensile stress) satisfy Expressions (1) and (2) below:
σ1/E1−σ2/E2<0 (1)
0<a1×σ1+a2×σ2 (2).

16. (canceled)

17. (canceled)

18. The manufacturing method according to claim 15, wherein the step (F) is performed after the step (E).

19. The manufacturing method according to claim 15, further comprising the step of providing a frame along a peripheral edge portion of the magnetic metal member.

20. The manufacturing method according to claim 15, wherein the first layer and the second layer are each formed by using a resin material or by using an inorganic material other than a metal material.

21. (canceled)

22. The manufacturing method according to claim 15, wherein either one of the first layer and the second layer is a metal layer.

23. The manufacturing method according to claim 15, wherein the substrate is a glass substrate, and a thermal expansion coefficient of the glass substrate is generally equal to or less than a thermal expansion coefficient of a material of each of the first layer and the second layer.

24. (canceled)

25. The manufacturing method according to claim 15, wherein the magnetic metal member has an open mask structure.

26. A method for manufacturing an organic semiconductor device comprising a step of vapor-depositing an organic semiconductor material on a work at the first temperature using the vapor deposition mask according to claim 1.
